(19) United States
(12) Patent Application Publication
(10) Pub. No.: US 2014/0366937 A1
(43) Pub. Date: Dec. 18, 2014

(54) SOLAR CELL

(71) Applicant: NEO SOLAR POWER CORP., HSINCHU CITY (TW)

(72) Inventors: Han Cheng Lee, HSINCHU CITY (TW); SHR-HAN FENG, HSINCHU CITY (TW); TZU-CHIN HSU, HSINCHU CITY (TW); YU-WEI TAI, HSINCHU CITY (TW); WEI-MING CHEN, HSINCHU CITY (TW)

(73) Assignee: NEO SOLAR POWER CORP., HSINCHU CITY (TW)

(21) Appl. No.: 14/177,662

(22) Filed: Feb. 11, 2014

(30) Foreign Application Priority Data
Jun. 18, 2013 (TW) 102121630

(51) Int. Cl. H01L 31/0224

(52) U.S. Cl. CPC H01L 31/022441
USPC 136/256

(57) ABSTRACT

A solar cell is disclosed, which includes: a semiconductor substrate, an anti-reflective layer, a passivation layer, a back electrode and back bus bar. The semiconductor substrate has a first surface and a second surface. The anti-reflective layer is disposed on the first surface. The back electrode is a continuous electrode or a flat electrode overlapping the whole back side of the solar cell. The continuous electrode or the flat electrode connects to the semiconductor substrate through a continuous opening. In another embodiment, the continuous electrode is passing through the passivation layer directly and connecting to the semiconductor substrate. That is, the solar cell includes a continuous opening or a continuous electrode.

### CROSS-REFERENCES TO RELATED APPLICATIONS

This non-provisional application claims priority under 35 U.S.C. §119(a) on Patent Application No. 102121630 filed in Taiwan, R.O.C. on 2013/06118, the entire contents of which are hereby incorporated by reference.

### BACKGROUND

1. Technical Field

The disclosure relates to a cell, and particularly to the structure of a crystalline solar cell.

2. Related Art

Development of solar cell technologies has become increasingly important due to the challenges posed by global warming. Among various solar cells, crystalline solar cells are currently popular in the market, due to their low cost and high efficiency.

Generally, a basic structure of a crystalline solar cell includes an anti-reflective layer, a semiconductor substrate, a back metal electrode and so forth from top to bottom. At the anti-reflective layer, a firing process is processed so that a front metal electrode and front bus bars are formed; while at the back metal electrode, back bus bars are formed. Via the bus bars, different solar cells are connected with each other so as to form a solar cell module.

How to achieve better efficiency is still an important topic for developing solar cell technologies. For example, a passivation layer is disposed on the back side of the solar cell so as to reduce the surface recombination rate. However, after the passivation layer is disposed, in order to form a proper conducting structure, the contact holes must be formed in the passivation layer, then the back electrodes are formed on the passivation layer and connect to the semiconductor substrate, or the back electrode directly penetrates the passivation layer and connect to the semiconductor substrate via firing manner.

For example, Taiwan patent (Patent number M422758) discloses a solar cell and a back electrode structure thereof, which further discloses that via directly passing through the holes on the passivation layer, conducting material, such as alumina pastes, is easily connected to the substrate so as to reduce the usage amount of the conducting material and reduce the cost of manufacturing the solar cell as well. In this prior art, via laser or etching, holes with different appearances are opened, such as lines, dashed lines, tilt stripes, round spots, pinholes or so forth, wherein the holes opened in the same line can be disposed continuously or discontinuously.

Although there are many different hole appearances disclosed in this prior art, it is hard to apply for manufacturing solar cells practically; that is to say, the hole opening methods should be chosen with the considerations of the manufacturing issue and the electrical conduction between bus bars of the solar cell. For example, if holes are opened discontinuously (such as in spotted manner), parts of the conducting material which are not connected to the bus bars will be an invalid structures. In addition, holes cannot be opened easily by lasers for linearly disposed back structures, so the speed of the laser hole opening is so slow, which also reduces the manufacturing throughput of the solar cell and raises the manufacturing cost.

Based on this, it is important to know how to design a proper back electrode structure. Further, in order to make the solar cell be manufactured easily, to reduce the manufacturing cost and to improve the efficiency of the solar cell, the design of the passivation layer should also be taken into account,

### SUMMARY

The present invention provides a solar cell including a semiconductor substrate, a passivation layer, a back electrode and a back bus bar. The semiconductor substrate has a first surface and a second surface. The passivation layer is disposed on the second surface and has at least one continuous opening. The back electrode is disposed on the passivation layer and covers the continuous opening. The back electrode is connected to the semiconductor substrate through the continuous opening. The back bus bar is connected to the back electrode.

The present invention further provides a solar cell including a semiconductor substrate, a passivation layer, at least one continuous electrode and a plurality of back bus bars. The semiconductor substrate has a first surface and a second surface. The passivation layer is disposed on the second surface. The continuous electrode is disposed on the passivation layer and directly penetrates the passivation layer so as to connect to the second surface of the semiconductor substrate. The back bus bars are connected to the continuous electrode.

According to the present invention, the solar cell can be manufactured easily, the cost for manufacturing the solar cell can be reduced, and the efficiency of the solar cell can be improved.

The detailed features and advantages of the disclosure are described below in great detail through the following embodiments, the content of the detailed description is sufficient for those skilled in the art to understand the technical content of the disclosure and to implement the disclosure there accordingly. Based upon the content of the specification, the claims, and the drawings, those skilled in the art can easily understand the relevant objectives and advantages of the present invention.

### BRIEF DESCRIPTION OF THE DRAWINGS

The disclosure will become more fully understood from the detailed description given herein below for illustration only, and thus not limitative of the present invention, wherein:

FIGS. 1A to 1E are bottom views of a first embodiment of a solar cell of the present invention, which shows a continuous opening, a continuous electrode and a plurality of back bus bars;

FIGS. 2A to 2C are cross-sectional views of the region 1 in FIGS. 1A and 1B along line A-A;

FIGS. 3A to 3E are bottom views of a second embodiment of a solar cell of the present invention, which shows a continuous opening, a continuous electrode and a plurality of back bus bars;

FIGS. 4A to 4C are cross-sectional views of the region 2 in FIGS. 1A and 1B along line B-B;

FIGS. 5A to 5D are bottom views of a third embodiment of a solar cell of the present invention, which shows a plurality of continuous openings, a plurality of continuous electrodes and a plurality of back bus bars;

FIGS. 6A to 6D are bottom views of a fourth embodiment of a solar cell of the present invention, which shows a plurality of continuous openings, a plurality of continuous electrodes and a plurality of back bus bars;

FIGS. 7A to 7D are bottom views of a fifth embodiment of a solar cell of the present invention, which shows a continuous opening, a continuous electrode and a plurality of back bus bars;

FIGS. 8A to 8D are bottom views of a sixth embodiment of a solar cell of the present invention, which shows a couple of continuous openings, a couple of continuous electrodes and a plurality of back bus bars;

FIGS. 9A to 9D are bottom views of a seventh embodiment of a solar cell of the present invention, which shows a couple of continuous openings, a couple of continuous electrodes and a plurality of back bus bars;

FIGS. 10A to 10D are bottom views of an eighth embodiment of a solar cell of the present invention, which shows a continuous opening, a continuous electrode and a plurality of back bus bars;

FIGS. 11A to 11D are bottom views of a ninth embodiment of a solar cell of the present invention, which shows a couple of continuous openings, a couple of continuous electrodes and a plurality of back bus bars;

FIGS. 12A to 12B are cross-sectional views of the region 1 in FIG. and 1B along line A-A in which the continuous electrode is formed directly via co-firing method rather than forming the continuous opening in advance;

FIGS. 13A to 13B are schematic views for showing the straight lines in the continuous openings have a dashed-line appearance; and

FIGS. 14A to 14C are schematic views for showing the two end points of each continuous opening are respectively disposed at the middle portions of the two opposite sides of the semiconductor substrate, and each two end points are connected with other two end points.

### DETAILED DESCRIPTION

In order to make the solar cell be manufactured easily, to reduce the manufacturing cost and to improve the efficiency of the solar cell at the same time, the disclosure provides a solar cell which is accomplished by designing the continuous electrodes which can be achieved by fast cutting the back electrode with laser cutting methods. Similarly, within the design of the continuous electrodes mentioned above, firing process is applied so as to connect the conducting material to the semiconductor substrate, which can also reduce the manufacturing cost of the solar cell and improve the solar cell efficiency. Some embodiments are disclosed as following.

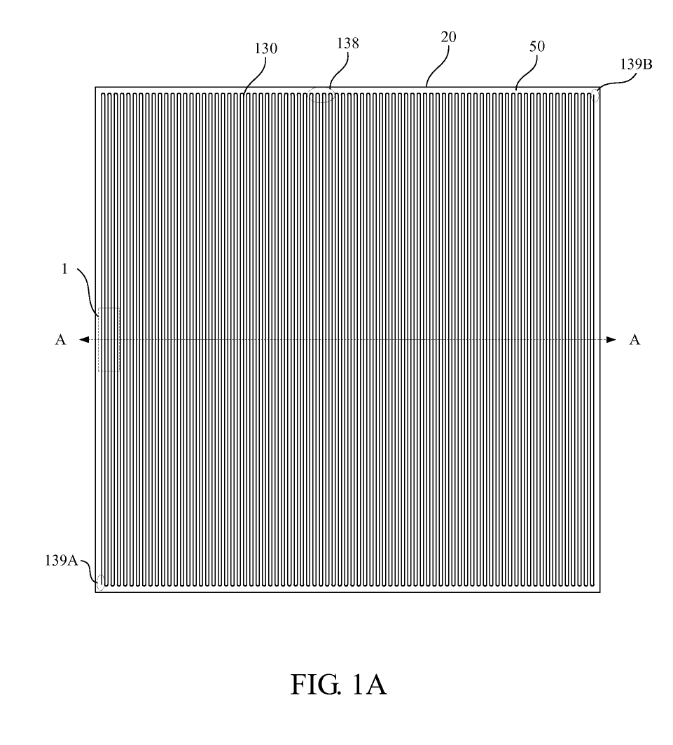

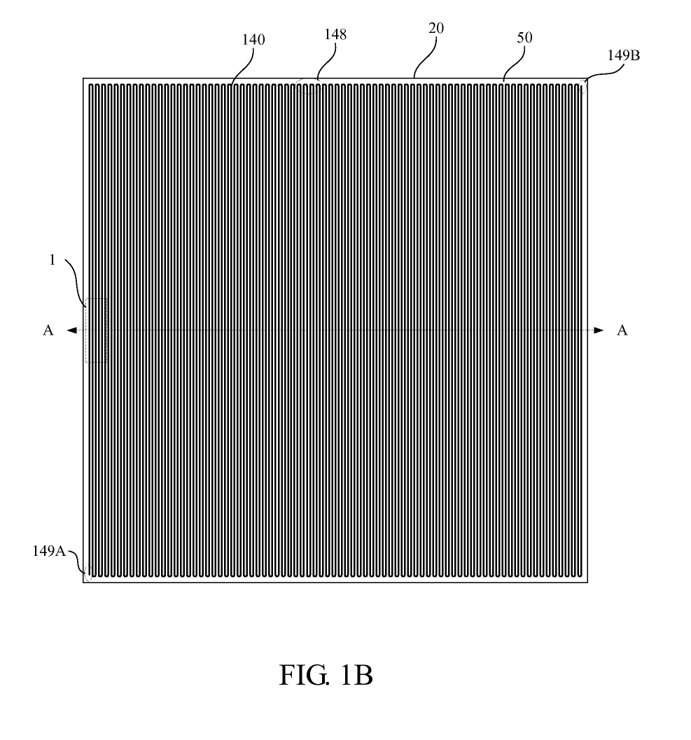

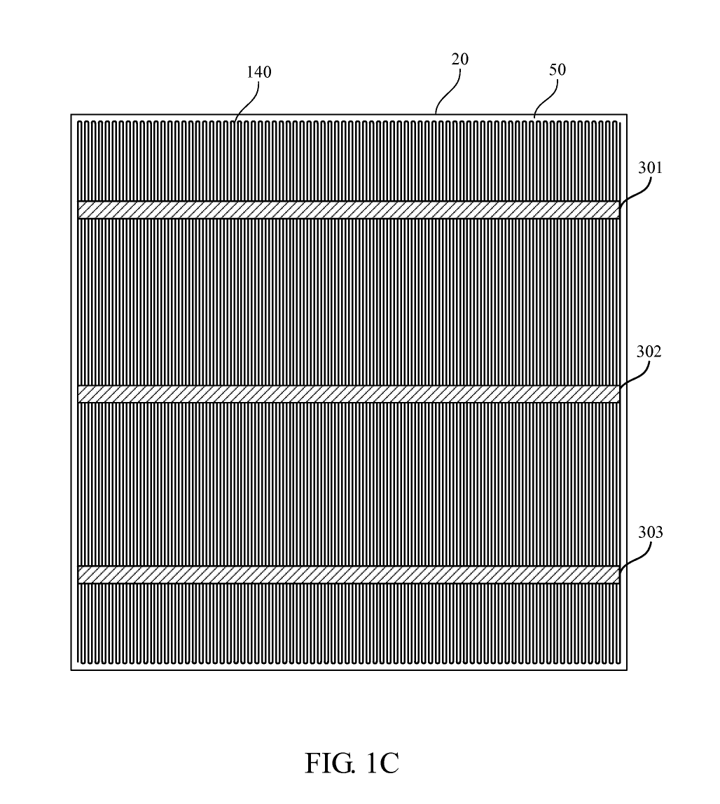

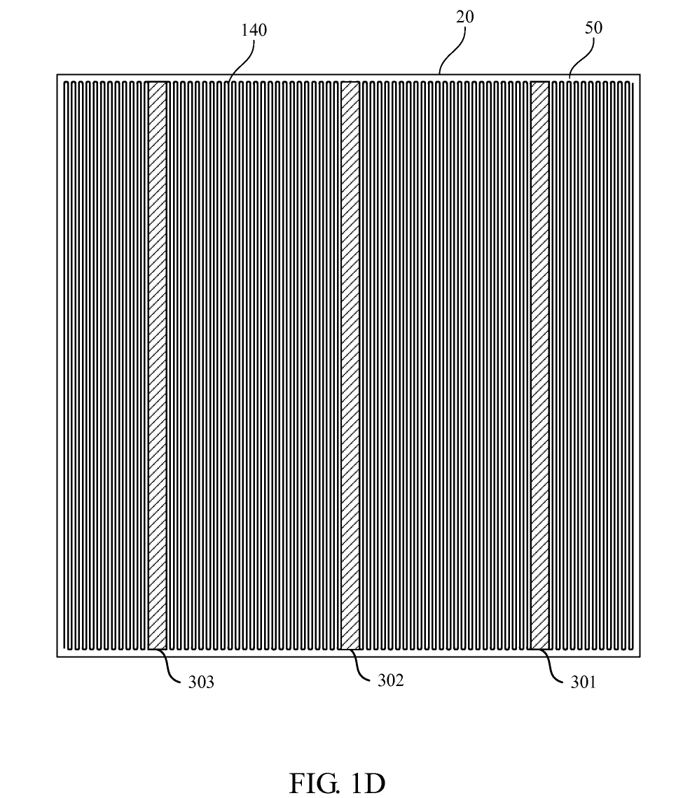

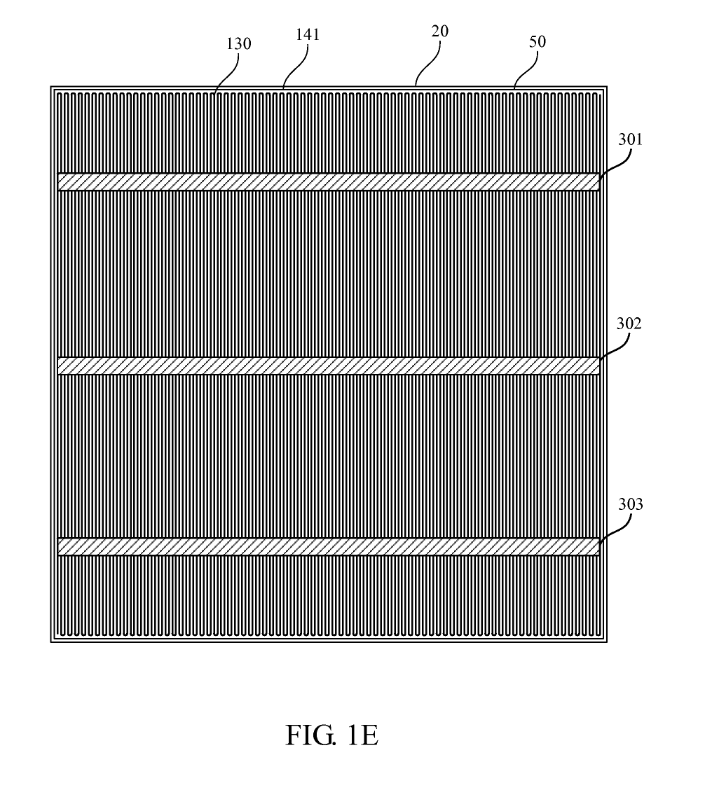

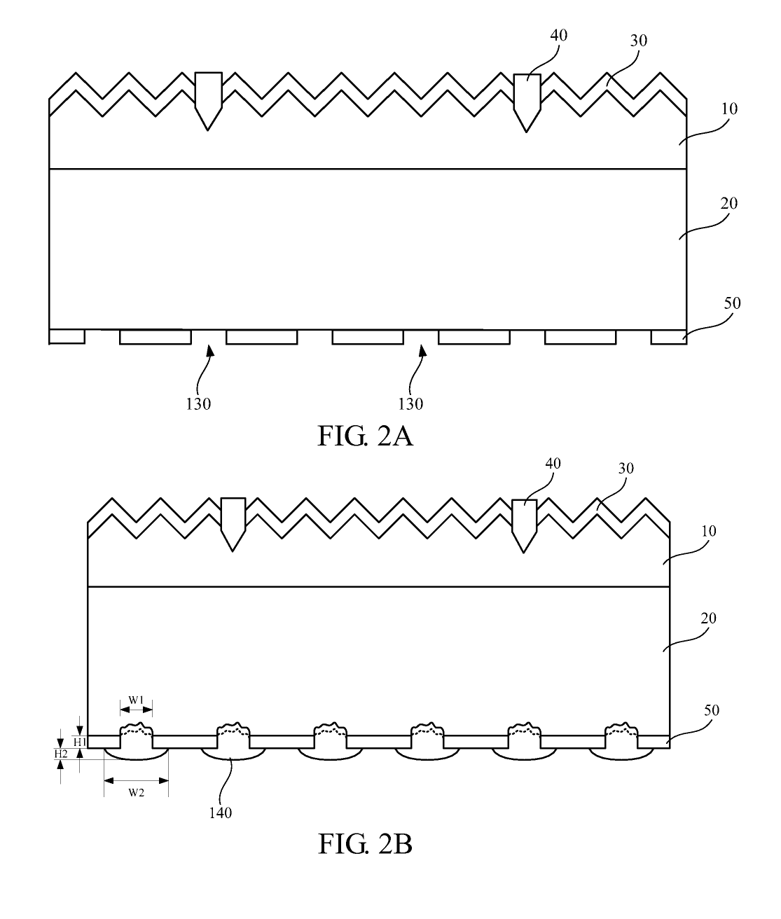

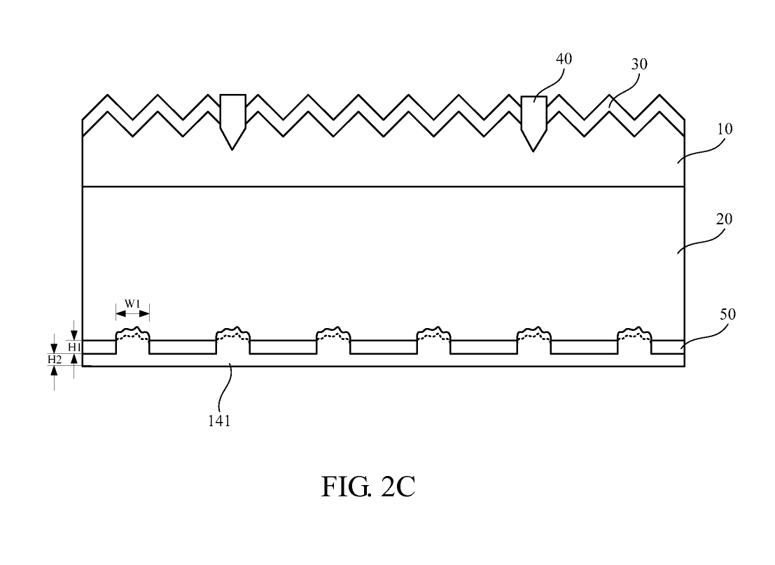

FIGS. 1A-1C are bottom views of the solar cell of the first embodiment of the present invention, which are schematic views of a continuous opening 130, a continuous electrode 140 and the back bus bars 301, 302, 303 respectively. Please refer to FIGS. 2A-2B, which are respectively the cross-sectional views of the FIG. 1A and FIG. 1B along line A-A of region 1.

In FIG. 1A and FIG. 2A, the continuous opening 130 is disposed in a passivation layer 50 of a second surface of a semiconductor substrate 20 (in this embodiment, the semiconductor substrate 20 is p-type); that is to say, the continuous opening 130 is disposed at a back side of the semiconductor substrate 20. An n-type doping layer 10 is disposed on a first surface (light incident surface) of the semiconductor substrate 20, and an anti-reflective layer 30 is disposed on the n-type doping layer 10. Normally, firing methods are applied so that the front electrode 40 can directly penetrate the anti-reflective layer 30 to electrically connect with the n-type doping layer 10. The continuous opening 130 on the passivation layer 50 is opened via laser cutting or etching methods.

When laser cutting methods are applied, since the design of the continuous linear characters are adapted in the continuous opening 130, the straight lines of the continuous opening 130 are parallel with each other, and the connecting portion 138 between the straight lines is curve, and the continuous opening 130 illustrates a continuous U-shape pattern. Consequently, the laser cutting equipment can be operated easily without repeatedly turn on and turn off the laser cutting equipment. So that the cutting speed can be increased, the cutting time can be reduced, and the damage produced during cutting the semiconductor substrate 20 can be significantly reduced.

Additionally, in FIG. 1A the continuous opening 130 includes two end points 139A, 139B, which are disposed at the two diagonal corners of the second surface of the semiconductor substrate 20. In this embodiment, since the number of the straight lines is an odd number, the end points 139A, 139B of the continuous opening 130 would be formed at the two diagonal corners of the semiconductor substrate 20, so that the laser cutting equipment can position the semiconductor substrate 20 easily.

Please refer to FIG. 1B and FIG. 2B, after the continuous opening 130 is formed, a continuous electrode 140 having two end points 149A and 149B is disposed on the continuous opening 130, wherein the continuous electrode 140 is formed by a conductive material, such as alumina pastes. The forming methods of the continuous electrode 140 are known by those who are skilled in the art so as to be omitted. In this embodiment, the conductive material is disposed on the continuous opening 130 via coating or printing methods, and the area of the conductive material is approximately equal to or larger than the area of the continuous opening 130 in FIG. 2A, so that the amount of the conductive material for forming the continuous electrode 140 is reduced as much as possible and the cost of the materials for manufacturing the solar cell is reduced as well. Similarly, in this embodiment the connecting portions 148 between the straight lines of the continuous electrode 140 are curve. In this embodiment, the continuous electrode 140 illustrates a continuous U-shape pattern.

Please refer to FIG. 1C, in which the back bus bars 301, 302, 303 are connecting to the continuous electrode 140. In this embodiment, the continuous electrode 140 is formed on the passivation layer 50, and then the back bus bars 301, 302, 303 are disposed on the continuous electrode 140. In some embodiments, the back bus bars 301, 302, 303 can be disposed on the passivation layer 50, and then the continuous electrode 140 is disposed on the back bus bars 301, 302, 303. Hereafter, the method for connecting the continuous electrode with the back bus bars is as the above description so as to be omitted. As mentioned above, the front electrode 40, the n-type doping layer 10, the semiconductor substrate 20, the continuous electrode 140 and the back bus bars 301, 302, 303 forms a conducting path.

Furthermore, the continuous opening 130 has a first width W1, which is defined from 10 micrometers to 300 micrometers; the portion of the continuous electrode 140 which is protruding from the passivation layer 50 has a second width W2. The second width W2 can be smaller than, equal to or larger than the first width W1; preferably, the second width W2 is larger than or equal to the first width W1. The passivation layer 50 has a first depth H1, which is defined from 5 nanometers to 300 nanometers; the portion of the continuous electrode 140 which is protruding from the passivation layer 50 has a protruding depth H2 defined from 5 micrometers to 40 micrometers. In this embodiment, the first width W1 is 40 micrometers, the second width W2 is 400 micrometers, the first depth H1 is 200 nanometers and the protruding depth H2 is 20 micrometers.

Please refer to FIG. 1D, showing one embodiment in which the back bus bars 301, 302, 303 of the FIG. 1C are aligned longitudinally rather than aligned transversely; namely, the back bus bars 301, 302, 303 shown in FIG. 1C is rotated by 90 degrees. This embodiment has the same advantages as mentioned above so as to be omitted.

Please refer to FIG. 1E, showing one embodiment in which the continuous electrode 140 is replaced by a back electrode 80 which is a flat electrode overlapping the whole back side of the solar cell so as to cover the continuous opening 130. Further Please refer to FIG. 2C, in which with the application of this embodiment, the continuous opening 130 and the back electrode 80 can be manufactured easily. Similarly, in this embodiment, the back bus bars 301, 302, 303 can be aligned longitudinally as well, similar to FIG. 1D.

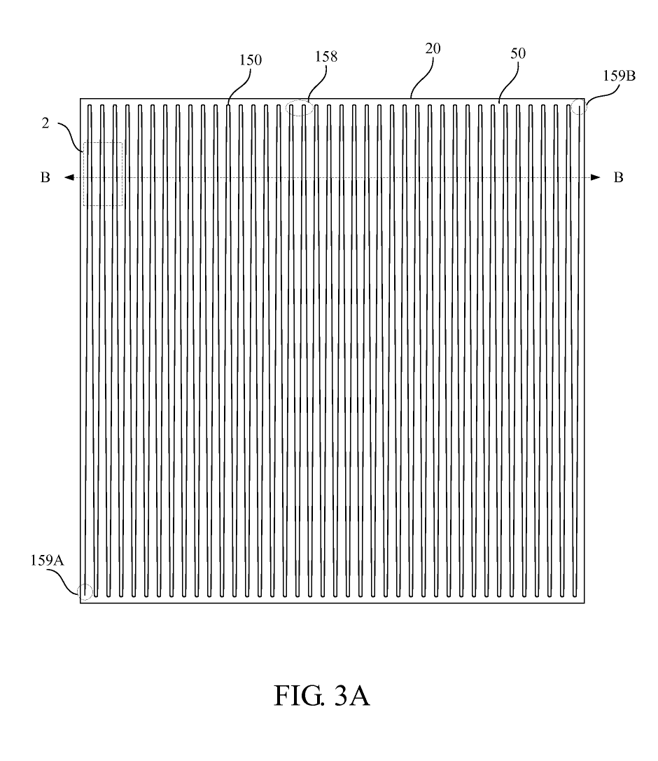

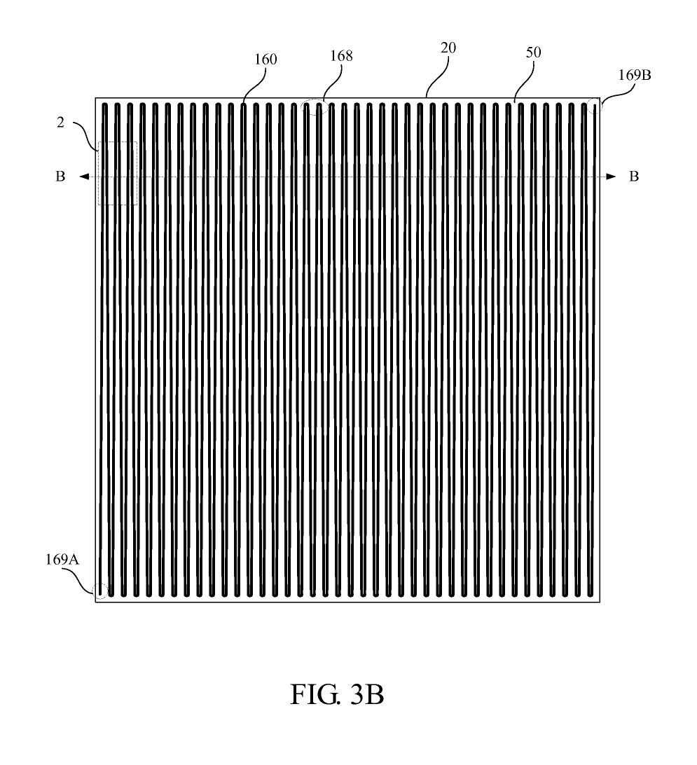

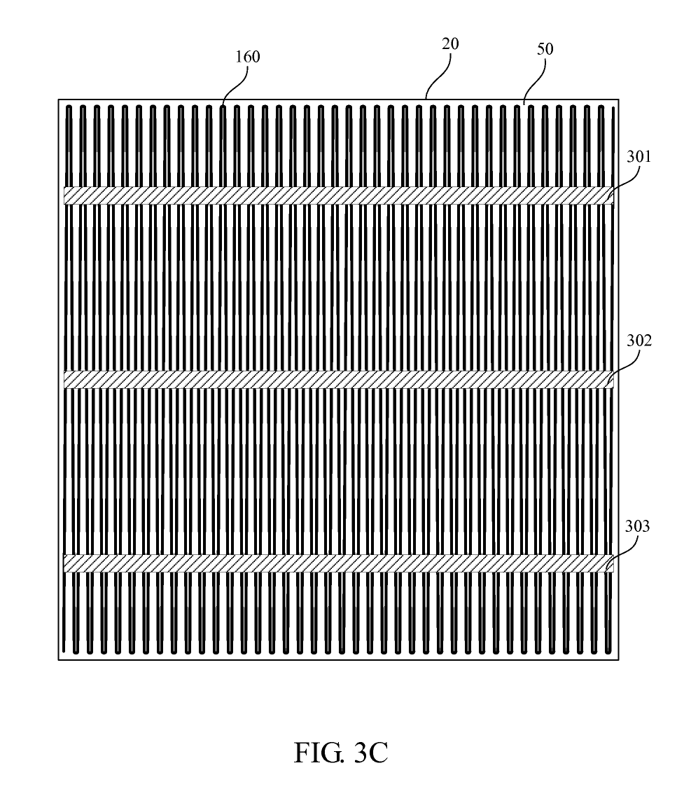

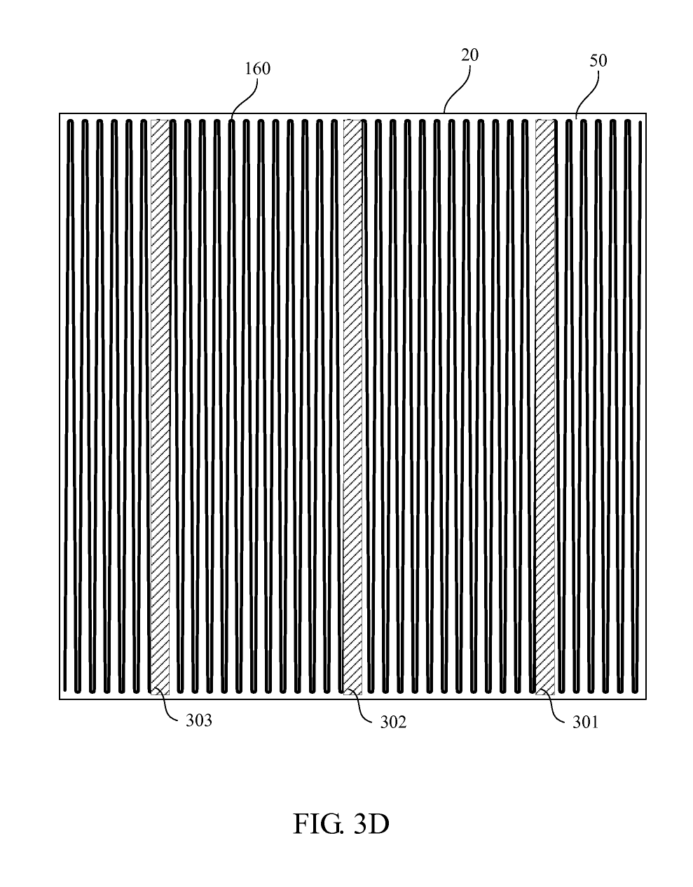

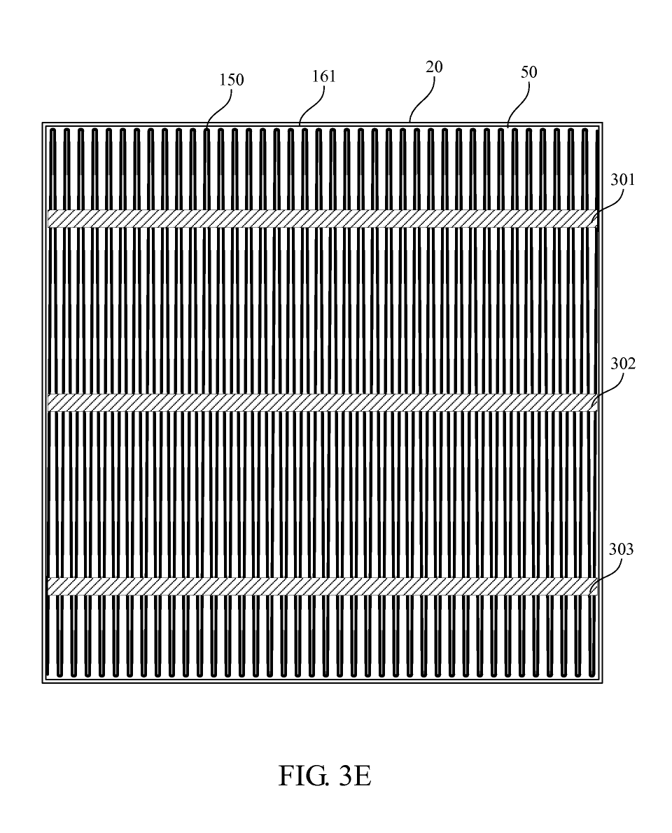

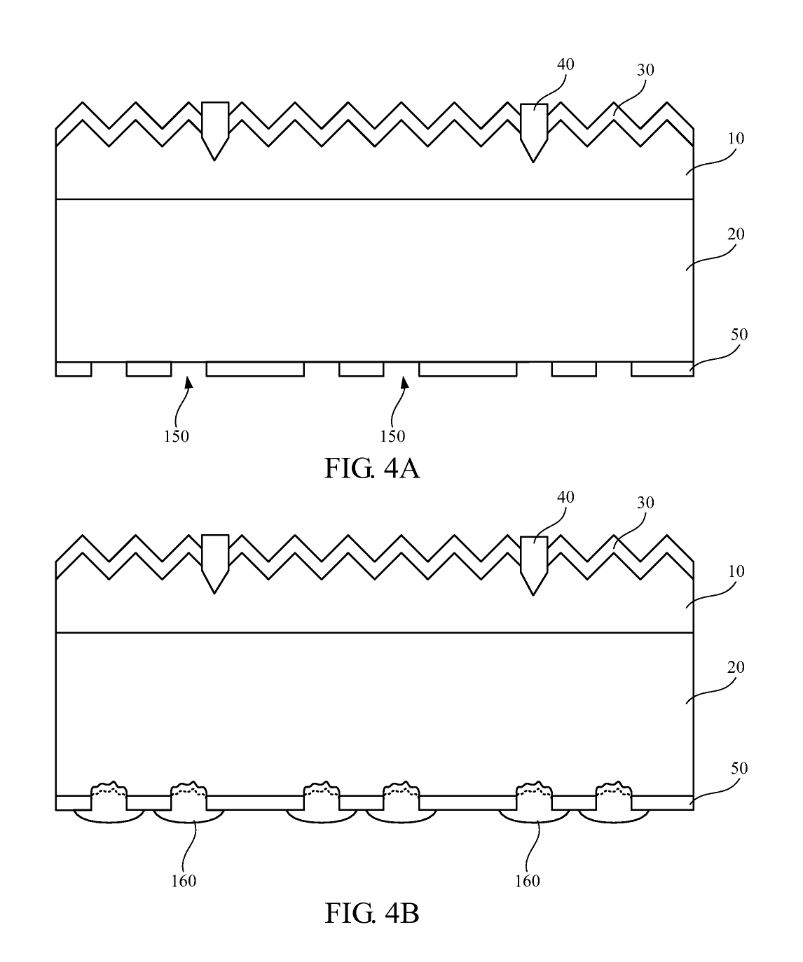

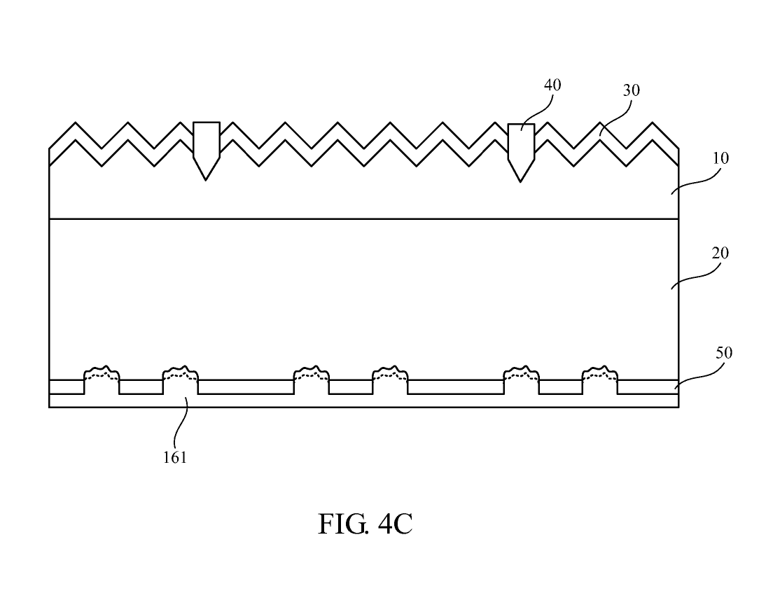

FIGS. 3A-3E are bottom views of a second embodiment of a solar cell of the present invention, which are schematic views of a continuous opening 150, a continuous electrode 160 and a plurality of back bus bars 301, 302, 303 respectively. Additionally, please refer to FIGS. 4A-4B, which are respectively the cross-sectional views of the FIG. 3A and FIG. 3B along line B-B of region 2.

In FIG. 3A and FIG. 4A, the continuous opening 150 is formed in the passivation layer 50 of the second surface of the semiconductor substrate 20 (in this embodiment, the semiconductor substrate 20 is p-type); that is to say, the continuous opening 150 is disposed at the back side of the semiconductor substrate 20. An n-type doping layer 10 is disposed on a first surface of the semiconductor substrate 20, and an anti-reflective layer 30 is disposed on the n-type doping layer 10, Normally, firing methods are applied so that the front electrode 40 can directly penetrate the anti-reflective layer 30 to electrically connect with the n-type doping layer 10. The continuous opening 150 is formed in the passivation layer 50 via laser cutting or etching methods. In this embodiment, the continuous opening 150 is composed of a plurality of linear openings and connected with the back bus bars 301, 302, 303 with an angle defined from 0 degree to 90 degrees.

When laser cutting methods are applied, since the design of the continuous linear characters are adapted in the continuous openings 150, and the connecting portions 158 between the linear openings of the continuous opening 150 can be curve or sharp angle. Consequently, the laser cutting equipment can be operated easily without repeatedly turned on and off the laser cutting equipment so the laser damage is reduced and the cutting speed can be increased and cutting time can be reduced. Additionally, since the laser cutting equipment does not need to be turned on and off repeatedly, the damage resulting from cutting the semiconductor substrate 20 can be significantly reduced.

Furthermore, In FIG. 3A, the continuous opening 150 includes two end points 159A, 159B, which are disposed at the two diagonal corners of the second surface of the semiconductor substrate 20. In this embodiment, since the number of the linear openings is an odd number, the end points 159A, 159B of the continuous opening 150 would be formed at the two diagonal corners of the semiconductor substrate 20, so that the laser cutting equipment can position the semiconductor substrate 20 easily.

Please refer to FIG. 3B and FIG. 4B, in which after the continuous opening 150 is formed, the continuous electrode 160 having two end points 169A, 169B is formed, wherein the continuous electrode 160 is formed by conductive material, such as alumina pastes. The forming methods of the continuous electrode 160 are sufficiently known by those who are skilled in the art, and so are omitted. In this embodiment, the conductive material is disposed on the continuous opening 150 with the area of the conductive material being approximately smaller than, equal to or larger than the area of the continuous opening 150, so that in this embodiment the amount of the conductive material for forming the continuous electrode 160 can be reduced as much as possible so as to reduce the cost of the materials for manufacturing the solar cell. Similarly, in this embodiment, the connecting portions 168 between the linear electrodes of the continuous electrode 160 are curve. In this embodiment, the continuous opening 150 and the continuous electrode 160 illustrate continuous V-shape patterns.

In addition, as comparing FIG. 1C with FIG. 3C, some differences will be revealed. In FIG. 1C, a plurality of linear electrodes which is disposed on and orthogonal to the back bus bars 301, 302, 303 are connected with each other; while in FIG. 3C, a plurality of linear electrodes which is disposed on but not orthogonal to the back bus bars 301, 302, 303 are connected with each other, with the angle between the linear electrodes and the back bus bars 301, 302, 303 being defined from 0 degree to 90 degrees. Therefore, the linear electrodes Which are orthogonal to the back bus bars 301, 302, 303 can be arranged in equidistantly, as shown in FIG. 1C, so that the intervals between each two adjacent linear electrodes of the continuous electrode 140 are the same. While in other embodiments, the interval between each two adjacent linear electrodes of the continuous electrode 160 can be different. The interval between the linear electrodes which are not orthogonal to the back bus bars depends on the position, as shown in FIG. 3C. In this embodiment, the width of the continuous opening 150 is 40 micrometers, the width of the continuous electrode 160 is 45 micrometers, the thickness of the passivation layer 50 is 150 nanometers, and the depth the continuous electrode 160 protruding from the surface of the passivation layer 50 is 15 micrometers. Therefore, with a back side view, the area of the continuous electrode 140 protruding from the surface of the passivation layer 50 is at least larger than 5% of the area of the continuous opening 130.

Please refer to FIG. 3C, in which the back bus bars 301, 302, 303 are connecting to the continuous electrode 160. Based on this, the front electrode 40, the n-type doping layer 10, the semiconductor substrate 20, the continuous electrode 160 and the back bus bars 301, 302, 303 forms a conducting path.

Please refer to FIG. 3D, showing one embodiment in which the back bus bars 301, 302, 303 of the FIG. 3C are aligned longitudinally rather than aligned transversely. This embodiment has the same advantages as mentioned above so as to be omitted.

Please refer to FIG. 3E, showing one embodiment in which the continuous electrode 160 is replaced by a back electrode 80, a flat electrode, which is forming on whole back side of the solar cell so as to cover the continuous opening 150. Please refer to FIG. 4C, with the application of this embodiment, the continuous opening 150 and the back electrode 80 can be manufactured easily.

In the embodiments shown in FIGS. 1A to 2B and FIGS. 3A to 4B, one continuous opening and one electrode (one continuous electrode or one back electrode), is adapted. In other embodiments, a plurality of continuous openings and a plurality of electrodes are adapted and disclosed as following.

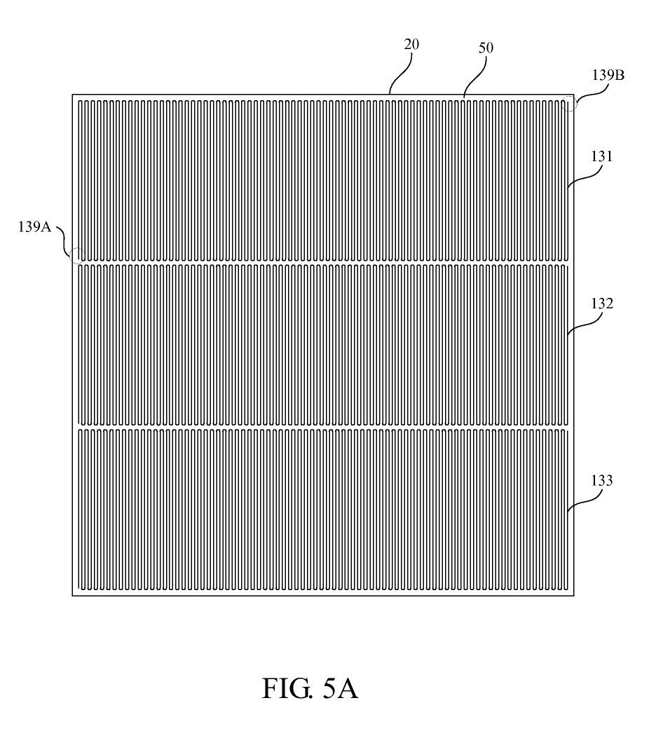

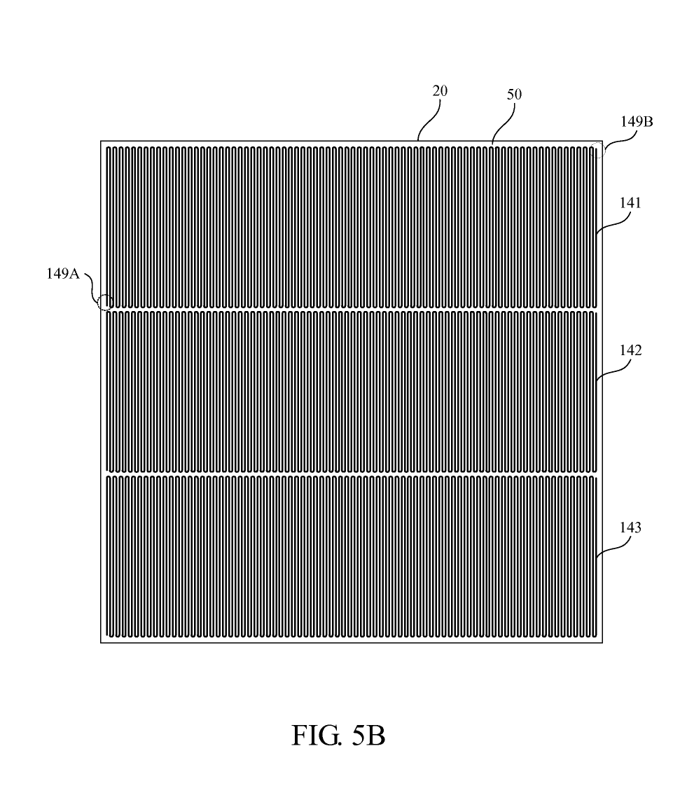

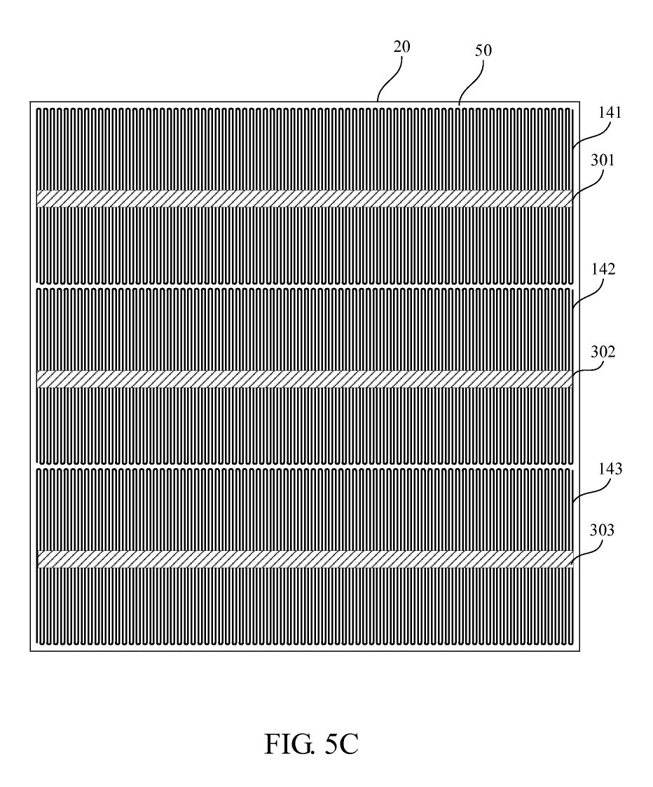

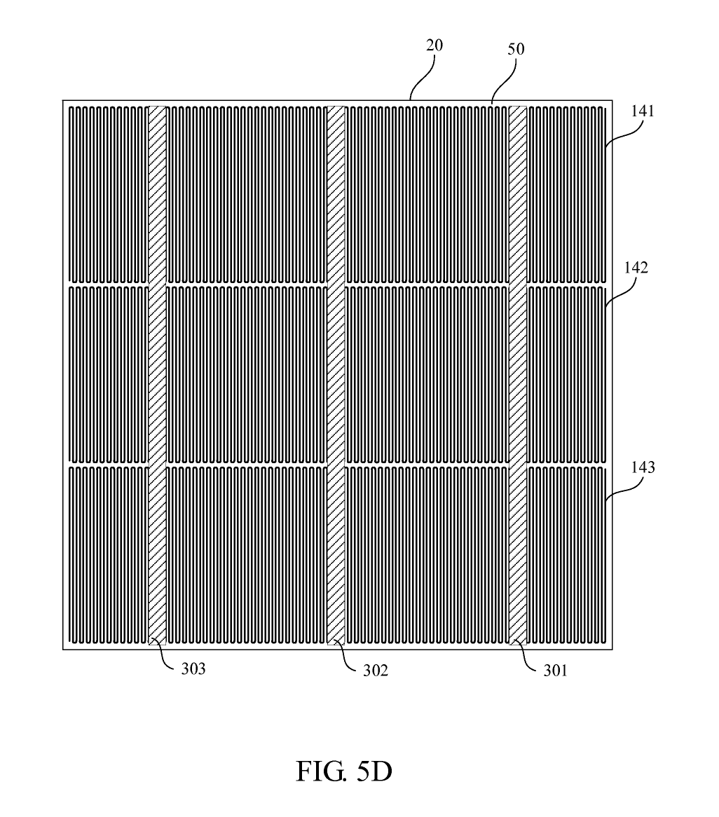

FIGS. 5A to 5D are bottom views of a third embodiment of a solar cell of the present invention, which shows a plurality of continuous openings 131, 132, 133, a plurality of continuous electrodes 141, 142, 143 and a plurality of back bus bars 301, 302, 303.

FIG. 5A illustrates the solar cell of present invention has three continuous openings 131, 132, 133 which are formed in the passivation layer 50 of the second surface of the semiconductor substrate 20 (p-type or n-type); the continuous openings 131, 132, 133 are formed at the back side of the semiconductor substrate 20. In this embodiment, the continuous openings 131, 132, 133 are formed by connecting a plurality of linear openings which is perpendicular to the back bus bars 301, 302, 303 with each other, in which the number of the linear openings is odd; namely, the angle between the linear openings and the back bus bars 301, 302, 303 is 90 degrees, as shown in FIG. 5C. Moreover, each continuous opening 131, 132, 133 has two end points 139A, 139B disposed at the two diagonal corners of the semiconductor substrate 20.

Please refer to FIG. 5B, in Which the number of the continuous electrodes 141, 142, 143 is three as well. The continuous electrodes 141, 142, 143 correspond to the back bus bars 301, 302, 303 individually, and each continuous electrode 141, 142, 143 has two end points 149A, 149B disposed at the two diagonal corners of the semiconductor substrate 20. Similarly, the connecting portions between the linear electrodes of the continuous electrodes 141, 142, 143 can be curve or sharp angle.

Please refer to FIG. 5D, showing one embodiment in which the back bus bars 301, 302, 303 of the FIG. 5C are aligned longitudinally rather than aligned transversely. This embodiment has the same advantages as mentioned above so as to be omitted. In this embodiment, the widths of the continuous openings 131, 132, 133 are 80 micrometers, the widths of the continuous electrodes 141, 142, 143 are 85 micrometers, the thickness of the passivation layer 50 is 100 nanometers, and the depth the continuous electrodes 141, 142, 143 protruding from the surface of the passivation layer 50 is 20 micrometers. Therefore, the area the continuous electrodes 141, 142, 143 protruding from the surface of the passivation layer 50 is at least larger than 5% of the area of the continuous openings 131, 132, 133. In some embodiments, the widths of the continuous openings 131, 132, 133 can be different, so that the width of the continuous electrodes 141, 142, 143 can be different as well.

Similarly, based on the structure similar to FIG. 3A, a plurality of continuous electrodes without perpendicular with the back bus bars can be accomplished.

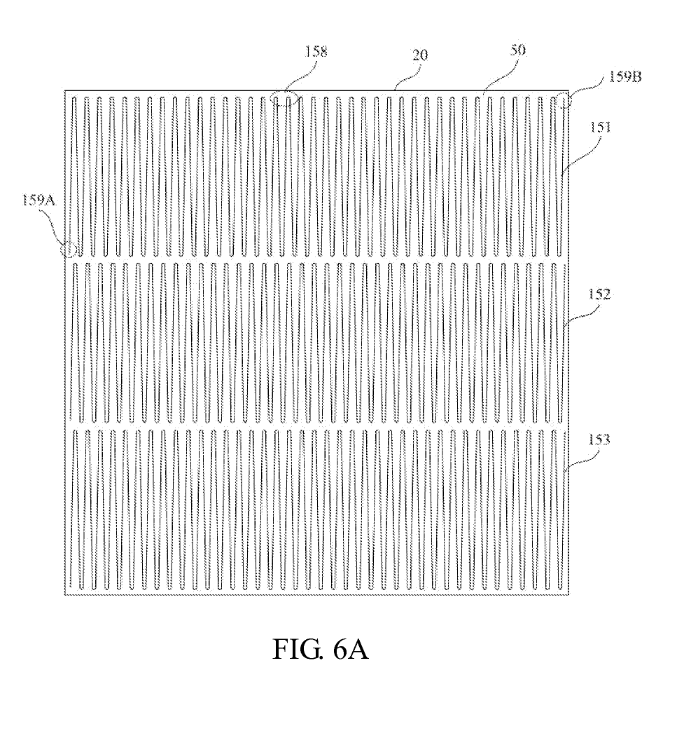

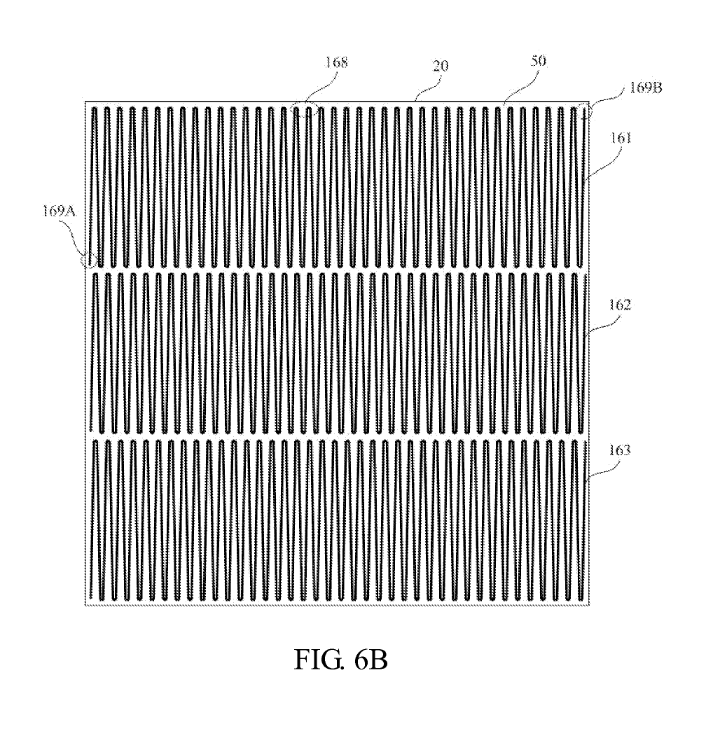

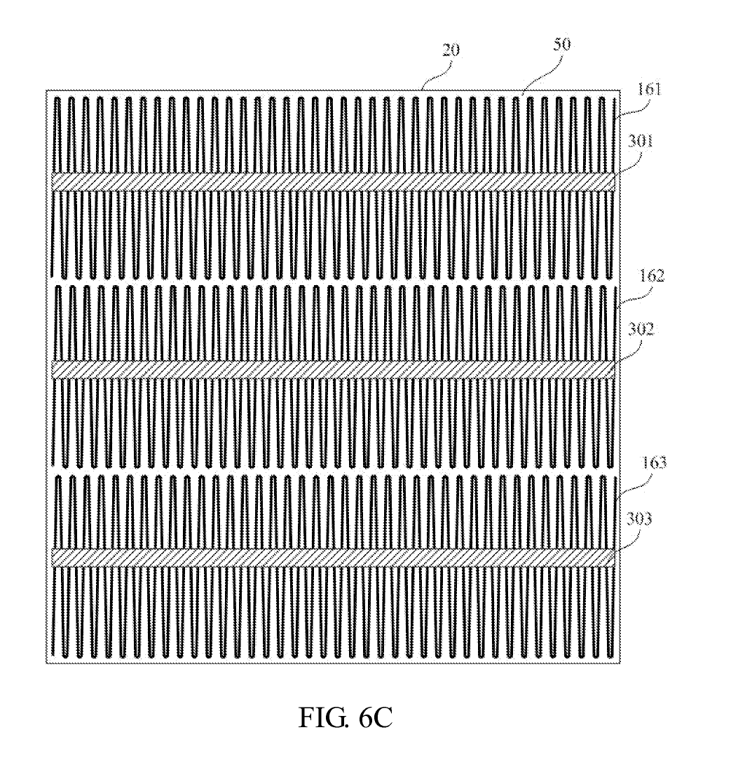

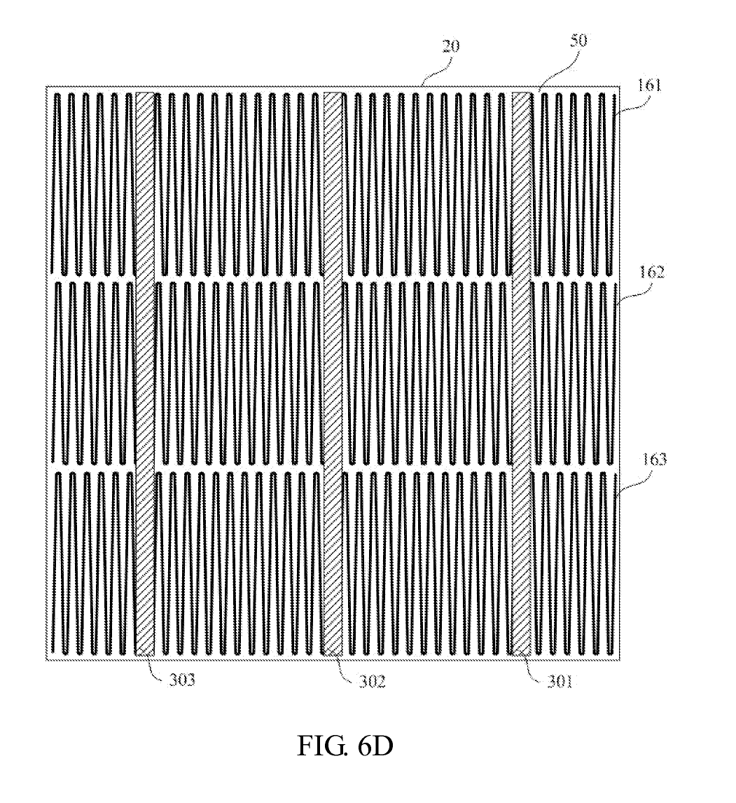

FIGS. 6A to 6D are bottom views of a fourth embodiment of a solar cell of the present invention, which shows a plurality of continuous openings 151, 152, 153, a plurality of continuous electrodes 161, 162, 163 and a plurality of back bus bars 301, 302, 303.

In FIG. 6A, the solar cell has three continuous openings 151, 152, 153. The continuous openings 151, 152, 153 are paralleled disposed in the passivation layer 50 of the second surface of the semiconductor substrate 20 (p-type or n-type) by a predetermined interval; that is to say, the continuous openings 151, 152, 153 are disposed at the back side of the semiconductor substrate 20, and the predetermined interval is a distance for making the adjacent two continuous openings do not connect with each other. In this embodiment, the continuous openings 151, 152, 153 are formed by connecting a plurality of linear openings with each other in which the angle between the linear openings and the back bus bars 301, 302, 303 is defined from 0 degree to 90 degrees, and the number of the linear openings is odd, as shown in FIG. 6C. Additionally, each continuous opening 151, 152, 153 has two end points 159A, 15913 disposed at the two diagonal corners of the semiconductor substrate 20.

Please refer to FIG. 6B, in which the solar cell has three continuous electrodes 161, 162, 163 corresponding to the back bus bars 301, 302, 303 individually, and each continuous electrode 161, 162, 163 has two end points 169A, 169B disposed at the two diagonal corners of the semiconductor substrate 20. Similarly, the connecting portions between the linear electrodes of the continuous electrodes 161, 162, 163 are curve. In this embodiment, the continuous opening 151, 152, 153 and the continuous electrode 161, 162, 163 illustrate continuous V-shape patterns.

Please refer to FIG. 6D, showing one embodiment in which the back bus bars 301, 302, 303 of the FIG. 6C are aligned longitudinally rather than aligned transversely. This embodiment has the same advantages as mentioned above so as to be omitted.

In addition to the condition that all the linear electrodes of the continuous electrodes are orthogonal to the back bus bars and the condition all the linear electrodes of the continuous electrodes are not orthogonal to the back bus bars, a mixed type design can also be adapted, as described in following embodiments.

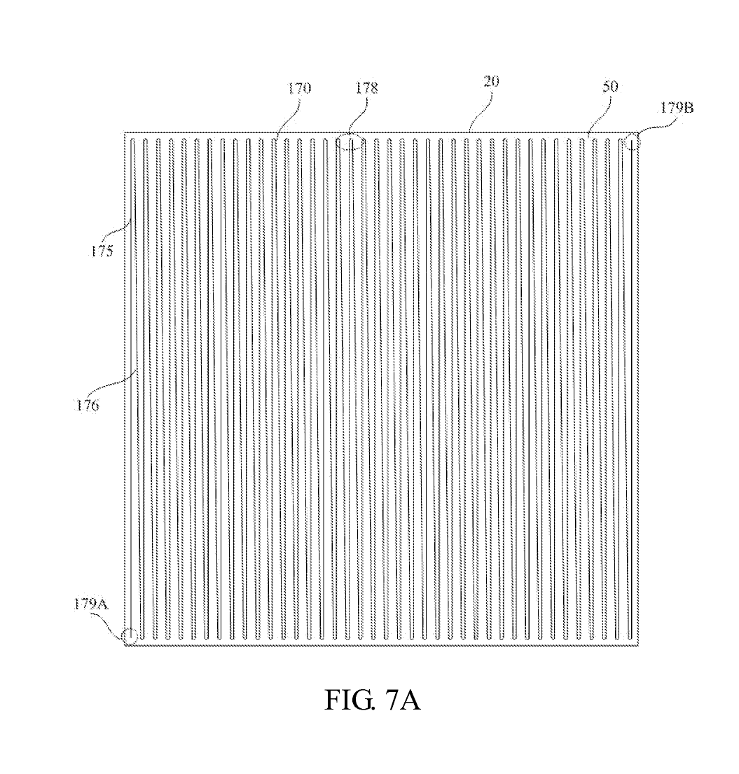

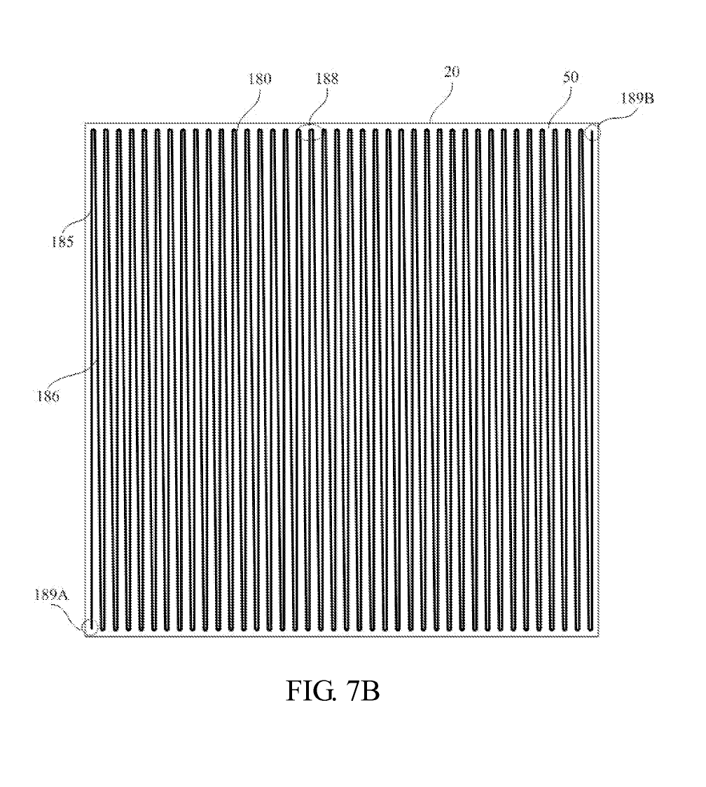

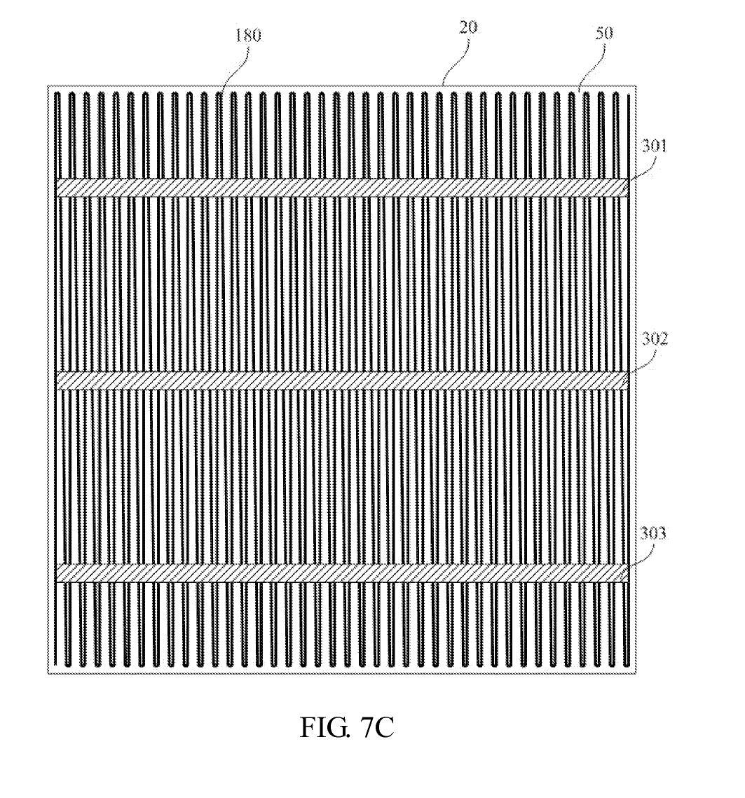

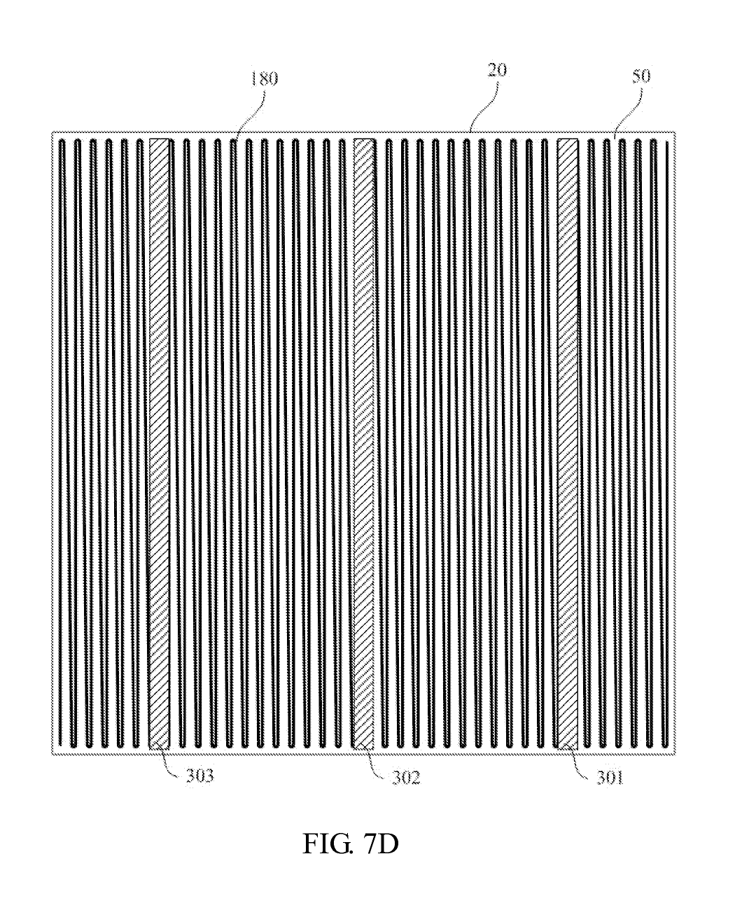

FIGS. 7A to 7D are bottom views of a fifth embodiment of a solar cell of the present invention, which shows a continuous opening 170, a continuous electrode 180 and a plurality of back bus bars 301, 302, 303.

In FIG. 7A, the continuous opening 170 is disposed in the passivation layer 50 of the second surface of the semiconductor substrate 20 (p-type or n-type); namely, the continuous opening 170 is disposed at the back side of the semiconductor substrate 20. In this embodiment, the continuous opening 170 is formed by connecting a plurality of first linear openings 175 and a plurality of second linear openings 176 with each other in which the first linear openings 175 are orthogonal to the back bus bars 301, 302, 303 and the second linear openings 176 are not orthogonal to the back bus bars 301, 302, 303; the summation of the number of the first linear openings 175 and the number of the second linear openings 176 is odd, as shown in FIG. 7C. Additionally, the continuous opening 170 has two end points 179A, 179B disposed at the two diagonal corners of the semiconductor substrate 20, and the connecting portions 178 between the first linear openings 175 and between the second linear openings 176 are curve.

Please refer to FIG. 7B, in which the continuous electrode 180 is connected with the back bus bars 301, 302, 303 and includes two end points 189A, 189B disposed at the two diagonal corners of the semiconductor substrate 20. Similarly, the connecting portions 188 of the linear electrodes of the continuous electrode 180 can be curve. In this embodiment, the continuous opening 175,176 and the continuous electrode 180 illustrate continuous Z-shape patterns.

Please refer to FIG. 7D, showing one embodiment in which the back bus bars 301, 302, 303 of the FIG. 7C are aligned longitudinally rather than aligned transversely. This embodiment has the same advantages as mentioned above so as to be omitted.

In addition to the embodiments mentioned above, a couple of continuous openings (electrodes), aligned symmetrically or asymmetrically can also be adapted to the present invention.

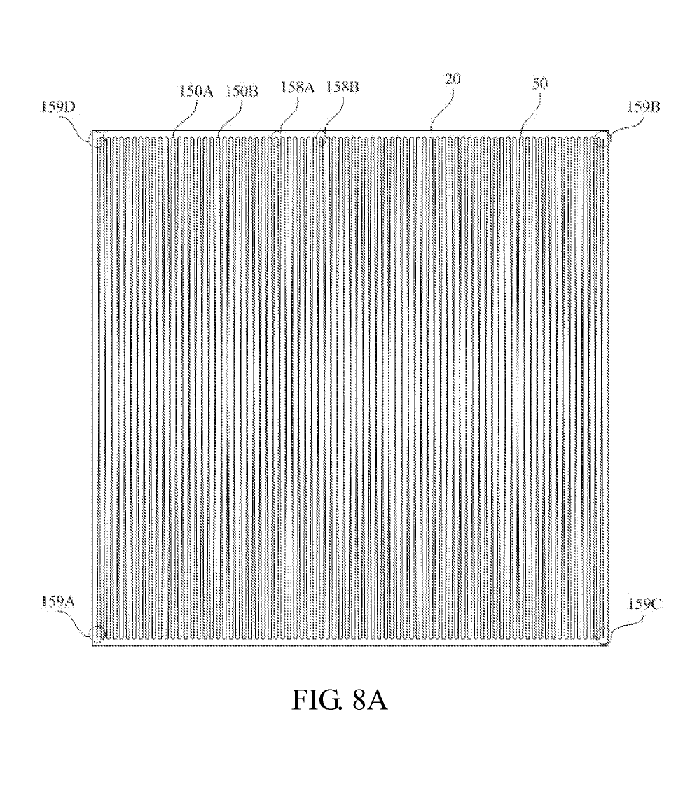

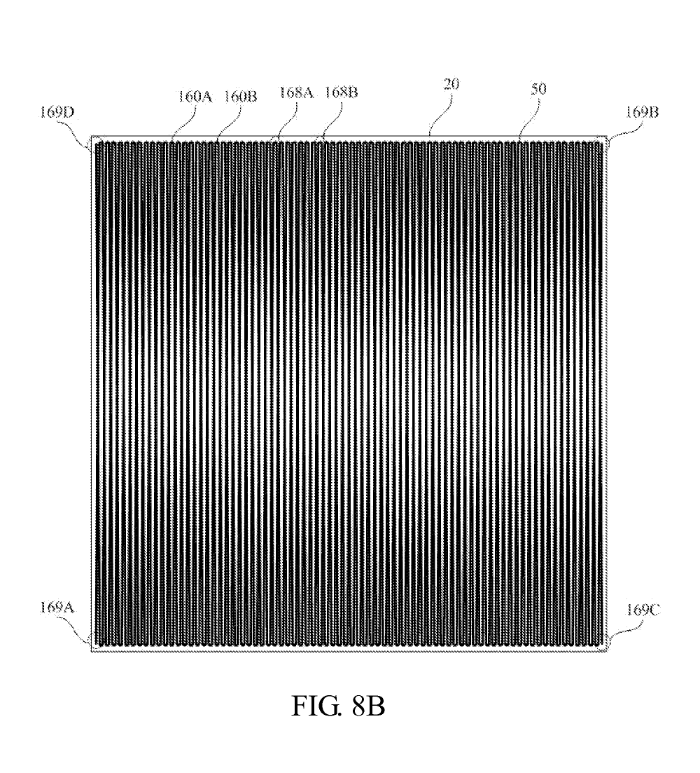

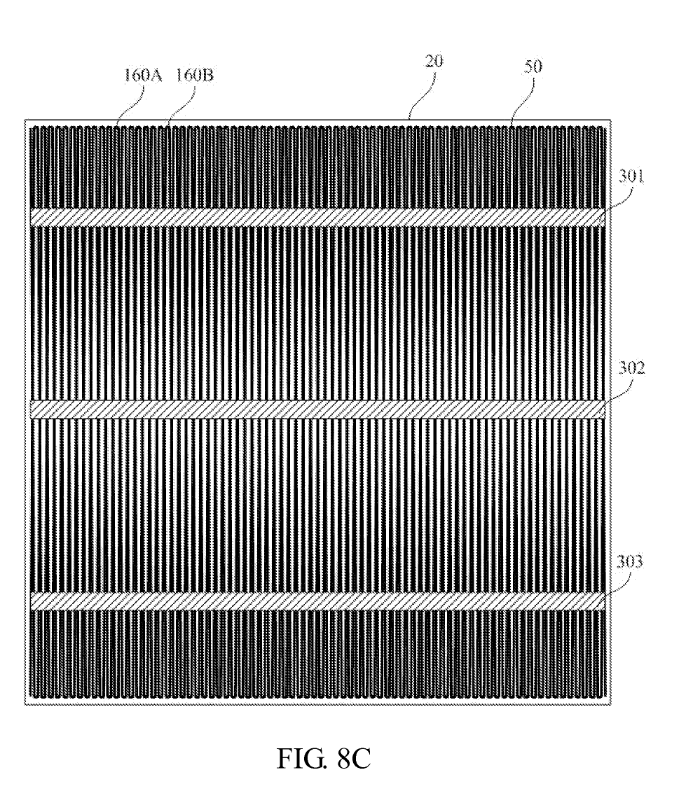

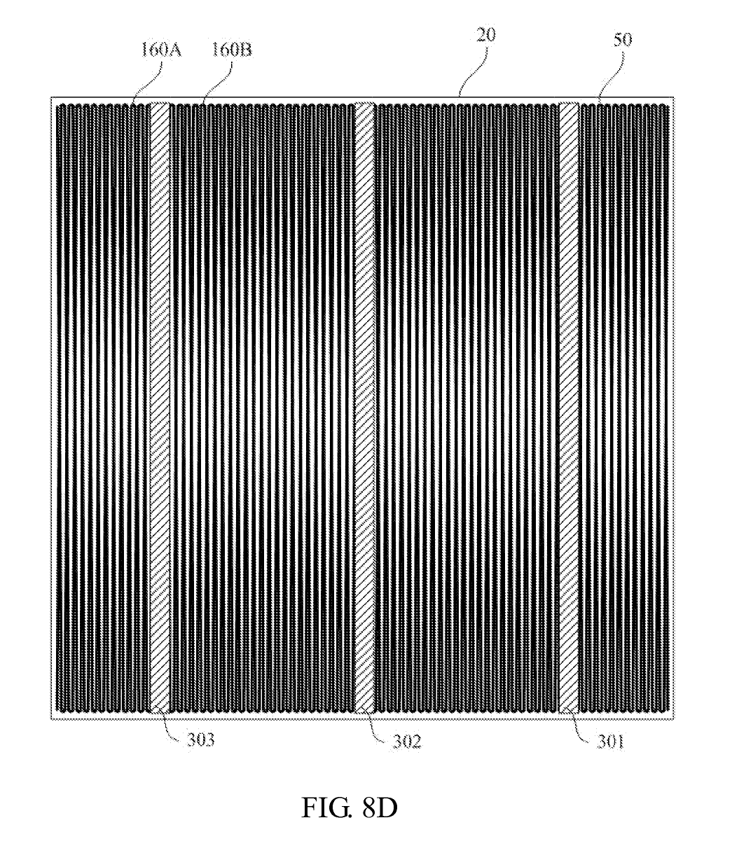

FIGS. 8A to 8D are bottom views of a sixth embodiment of a solar cell of the present invention, which shows a couple of continuous openings 150A, 150B, a couple of continuous electrodes 160A, 160B and a plurality of back bus bars 301, 302, 303.

In FIG. 8A, the two continuous openings 150A, 150B are disposed in the passivation layer 50 of the second surface of the semiconductor substrate 20 (p-type or n-type); namely, the two continuous openings 150A, 150B are disposed at the back side of the semiconductor substrate 20. In this embodiment, the two continuous openings 150A, 150B are respectively formed by connecting a plurality of linear openings with each other, in which the linear openings are not orthogonal to the back bus bars 301, 302, 303 and the number of the linear openings is odd, as shown in FIG. 8C. Additionally, the continuous opening 150A has two end points 159A, 159B disposed at the two diagonal corners of the semiconductor substrate 20; the continuous opening 150B has two end points 159C, 159D disposed at the two diagonal corners of the semiconductor substrate 20. Further, the connecting portions between the linear openings of the continuous openings 150A, 150B can be curve or sharp angle.

Please refer to FIG. 8B, in which the continuous electrode 160A has two end points 169A, 169B disposed at the two diagonal corners of the semiconductor substrate 20; the continuous opening 160B has two end points 169C, 169D disposed at the two diagonal corners of the semiconductor substrate 20. Similarly, the connecting portions between the linear electrodes of the continuous electrodes 160A, 160B can be curve or sharp angle.

Please refer to FIGS. 8C and 8D, in FIG. 8C, in which the continuous electrodes 160A, 160B are electrically connected to the back bus bars 301, 302, 303; while in FIG. 8D, the back bus bars 301, 302, 303 are aligned longitudinally. These embodiments have the same advantages as mentioned above so as to be omitted.

For designing a pair of continuous openings (electrodes), aligned symmetrically and interlaced, the minimum number of the linear openings and the linear electrodes is two; that is to say, structures formed by two or more than two linear openings and linear electrodes are possible to be embodied.

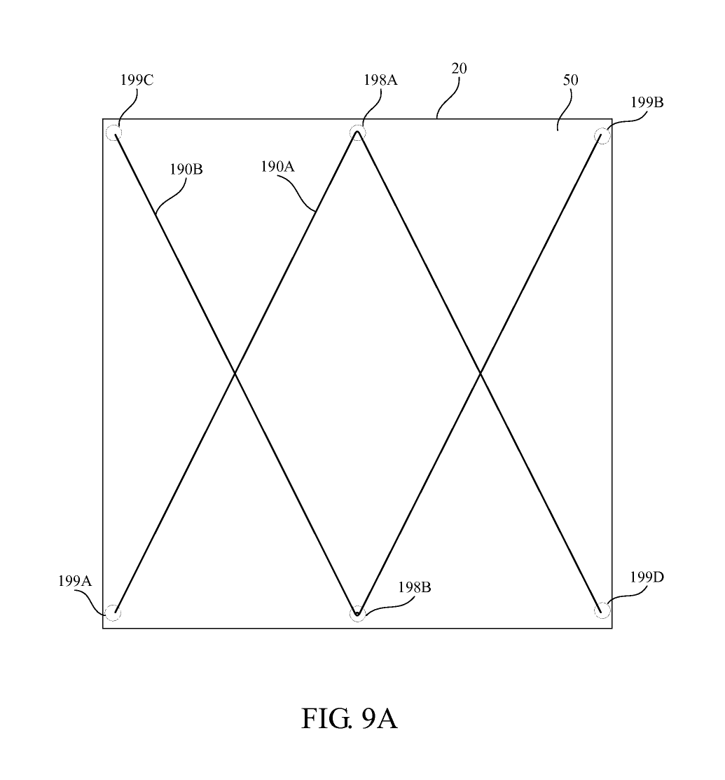

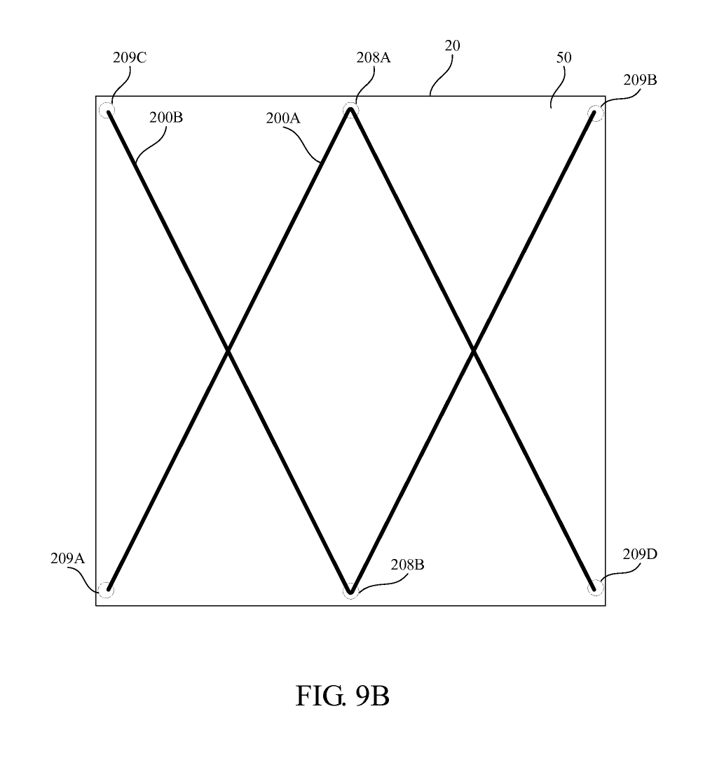

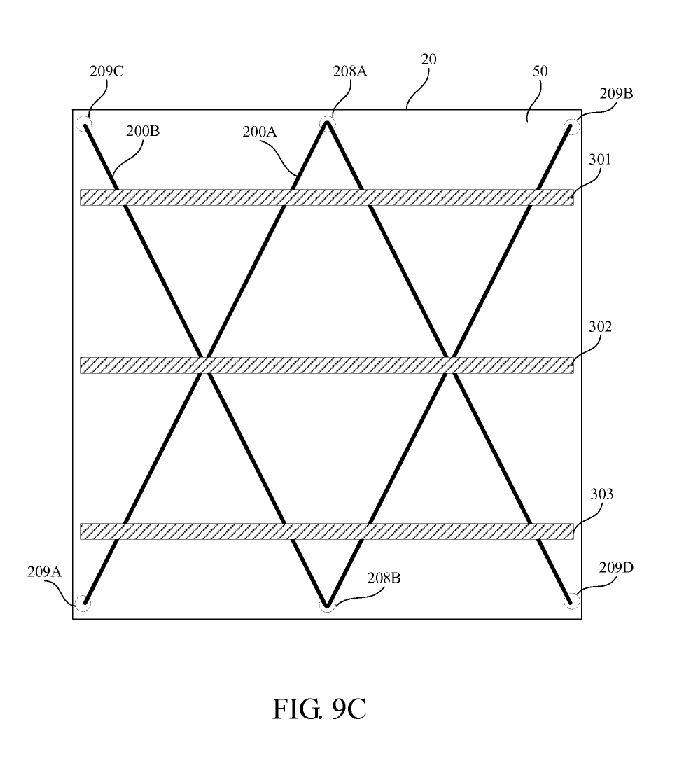

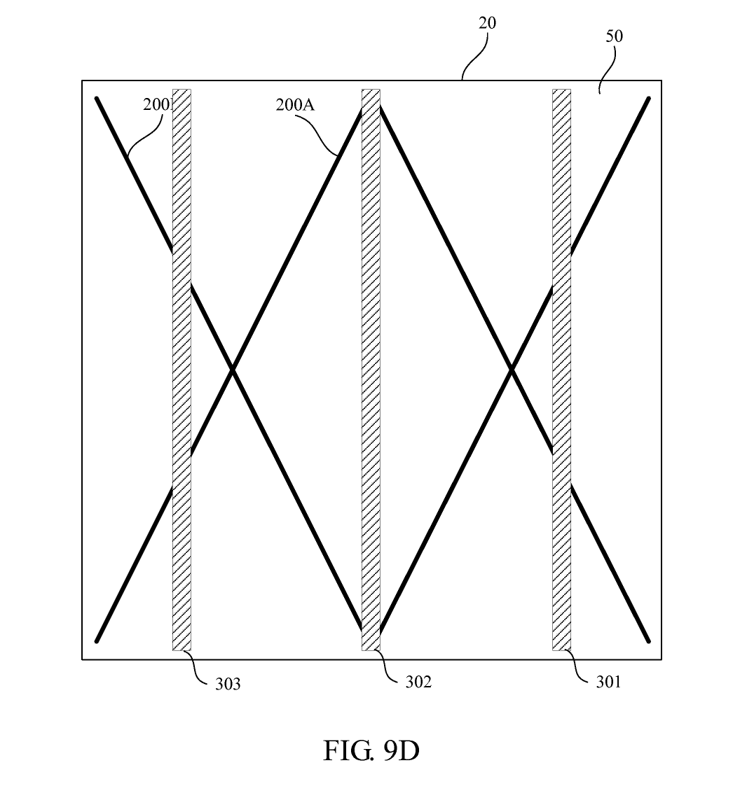

FIGS. 9A to 9D are bottom views of a seventh embodiment of a solar cell of the present invention, which shows a couple of continuous openings 190A, 190B, a couple of continuous electrodes 200A, 200B and a plurality of back bus bars 301, 302, 303.

In FIG. 9A, the two continuous openings 190A, 190B are disposed in the passivation layer 50 of the second surface of the semiconductor substrate 20 (p-type or n-type); namely, the two continuous openings 190A, 190B are disposed at the back side of the semiconductor substrate 20. In this embodiment, the two continuous openings 190A, 190B are formed by respectively connecting two linear openings with each other, in which the two linear openings are not orthogonal to the back bus bars 301, 302, 303, as shown in FIG. 9C. Moreover, the continuous opening 190A has two end points 199A, 199D disposed at same side of the semiconductor substrate 20; the continuous opening 190B has two end points 199B, 199C disposed at the other side of the semiconductor substrate 20. Further, the connecting portions 198A, 198B between the linear openings of the continuous openings 190A, 190B can be curve or sharp angle.

Please refer to FIG. 9B, in which the two continuous electrodes 200A, 200B are connected with the back bus bars 301, 302, 303. And, the continuous electrode 200A has two end points 209A, 209D disposed at one side of the semiconductor substrate 20; the continuous electrode 200B has two end points 209B, 209C disposed at the other side of the semiconductor substrate 20. Similarly, the connecting portions 208A, 208B between the linear electrodes of the continuous electrodes 200A, 200B can be curve or sharp angle.

Please refer to FIG. 9D, showing one embodiment in which the back bus bars 301, 302, 303 of the FIG. 9C are aligned longitudinally rather than aligned transversely. This embodiment has the same advantages as mentioned above so as to be omitted.

In this embodiment, the end points at the four corners make the continuous openings and the continuous electrodes be positioned easily during manufacturing so as to improve the preciseness and the yield rate.

The embodiment shown in FIGS. 9A to 9D describe the design that the end points are disposed at the same side, and in this embodiment, the number of the linear openings and the number of the linear electrodes are even. In some embodiments, a plurality of linear openings (linear electrodes), are connected with each other, with the number of the linear openings (linear electrodes), being even so as to dispose the end points at the same side.

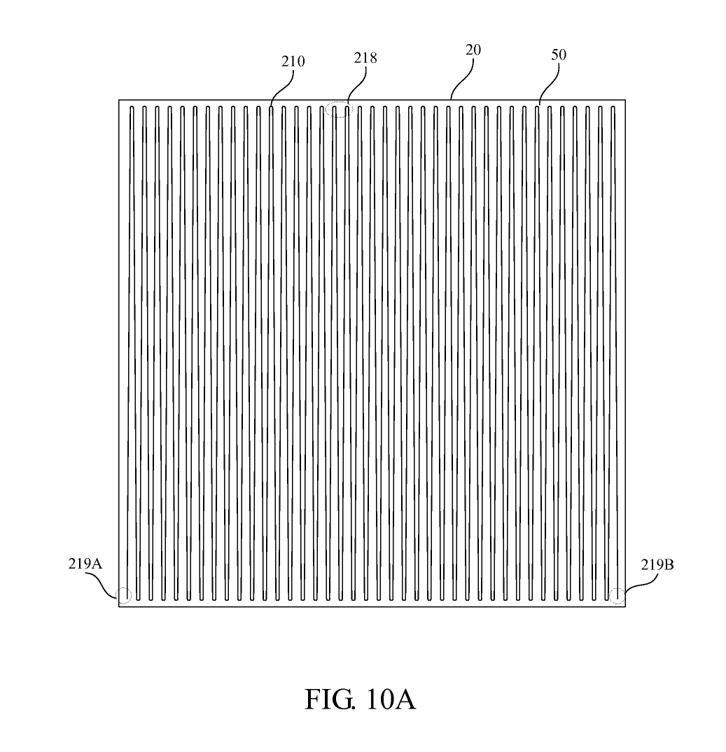

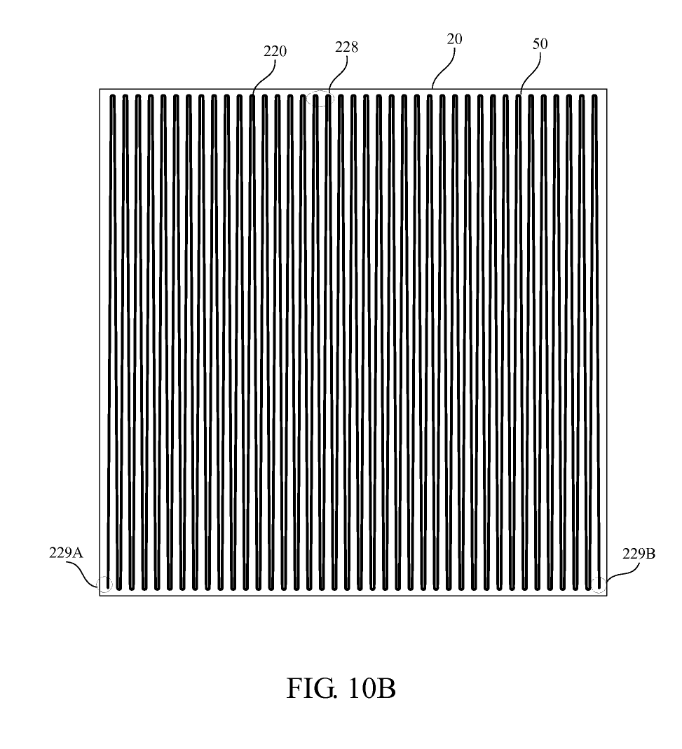

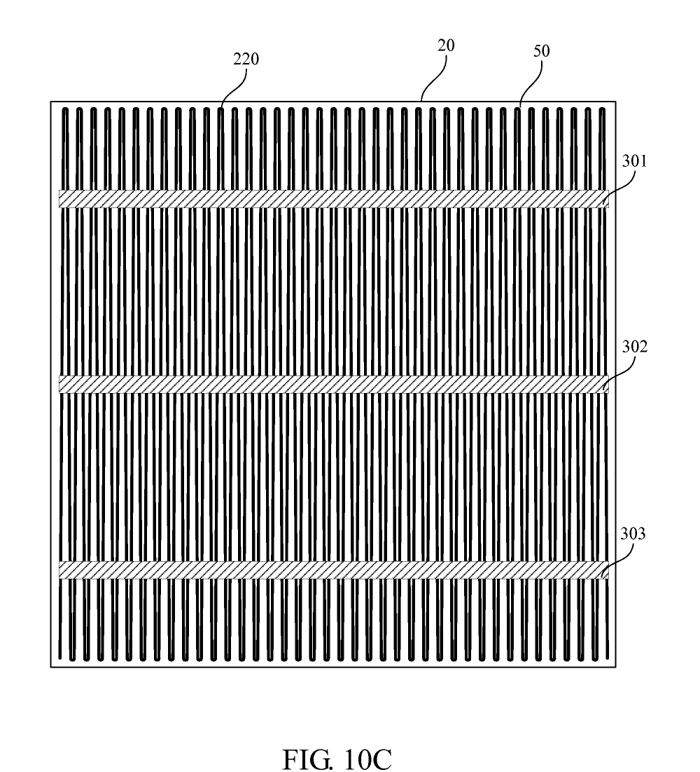

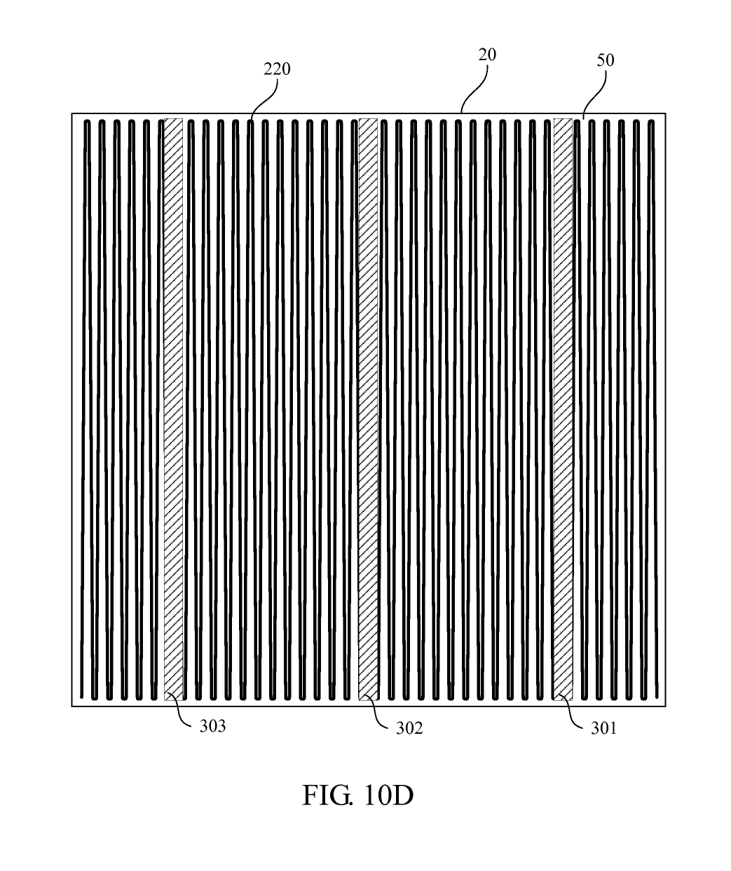

FIGS. 10A to 10D are bottom views of an eighth embodiment of a solar cell of the present invention, which shows a continuous opening 210, a continuous electrode 220 and a plurality of back bus bars 301, 302, 303.

In FIG. 10A, the continuous opening 210 is disposed in the passivation layer 50 of the second surface of the semiconductor substrate 20 (p-type or n-type); namely, the continuous opening 210 is disposed at the back side of the semiconductor substrate 20. In this embodiment, the continuous opening 210 is formed by connecting a plurality of linear openings with each other in which the linear openings are not orthogonal to the back bus bars 301, 302, 303 and the number of the linear openings is even, as shown in FIG. 10C. Further, the continuous opening 210 has two end points 219A, 219B disposed at the same side of the semiconductor substrate 20, and the connecting portions 218 between the linear openings of the continuous opening 210 are curve.

Please refer to FIGS. 10B and 10C, in which the continuous electrode 220 is connected with the back bus bars 301, 302, 303. And, the continuous electrode 220 has two end points 229A, 229B disposed at the same side of the semiconductor substrate 20. Similarly, the connecting portions 228 between the linear electrodes of the continuous electrode 220 are curve.

Please refer to FIG. 10D, showing one embodiment in which the back bus bars 301, 302, 303 of the FIG. 10C are aligned longitudinally rather than aligned transversely. This embodiment has the same advantages as mentioned above so as to be omitted.

In this embodiment, the end points are disposed at the same side of the semiconductor substrate so that the continuous openings and the continuous electrodes are positioned easily during manufacturing so as to improve the preciseness and the yield rate.

Based on the design concepts mentioned above, the disclosure may also provide a structure in which the continuous openings and the continuous electrodes are aligned symmetrically or asymmetrically with the number of the linear openings being even, or a structure in which at least one pair of continuous openings and at least one pair of continuous electrodes thereof are interlaced with each other.

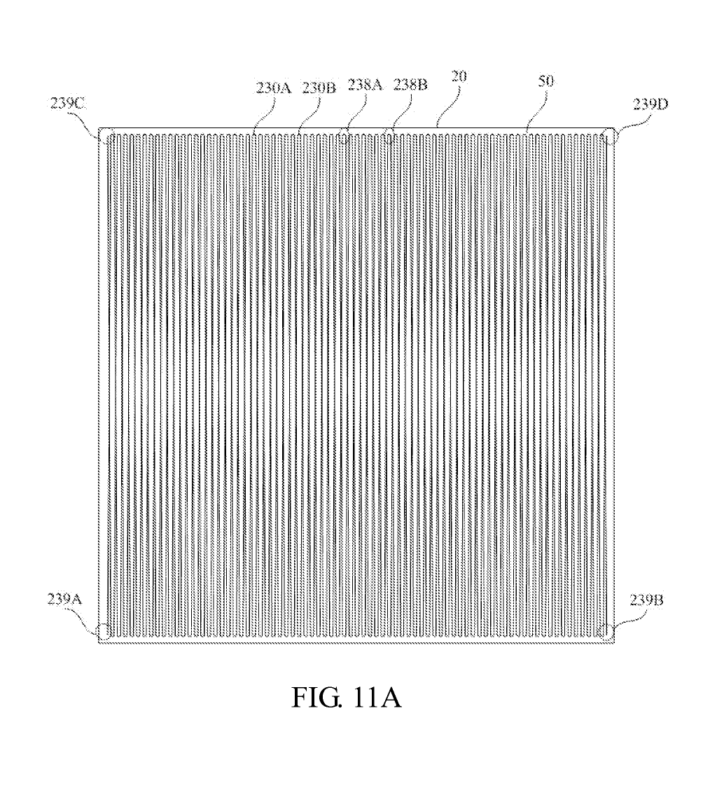

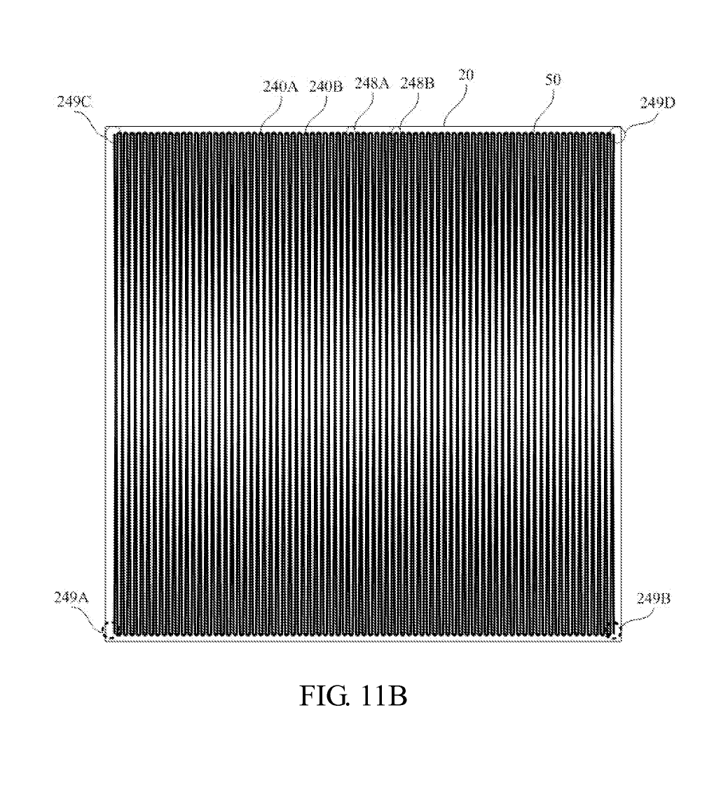

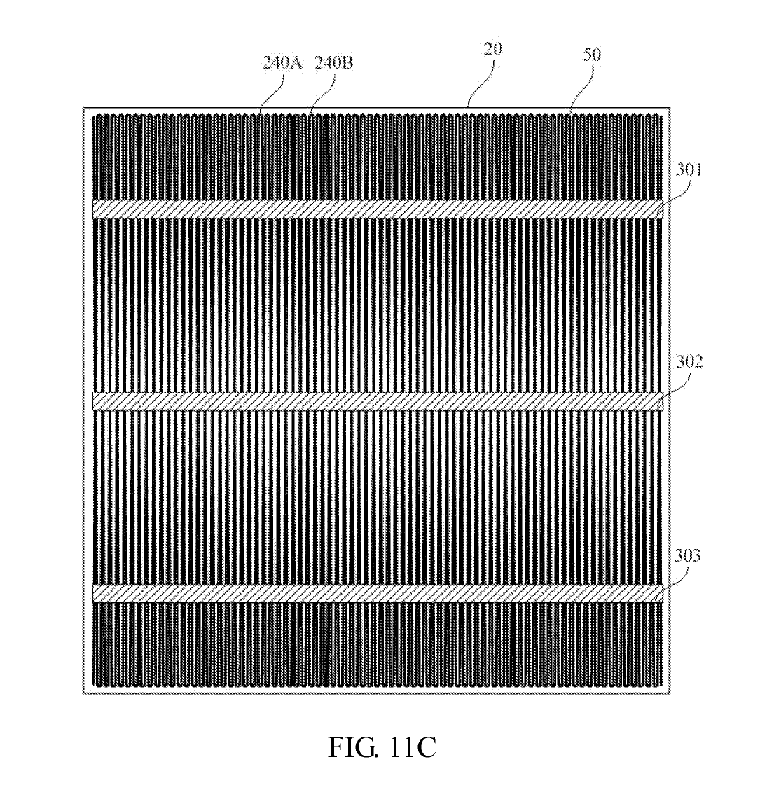

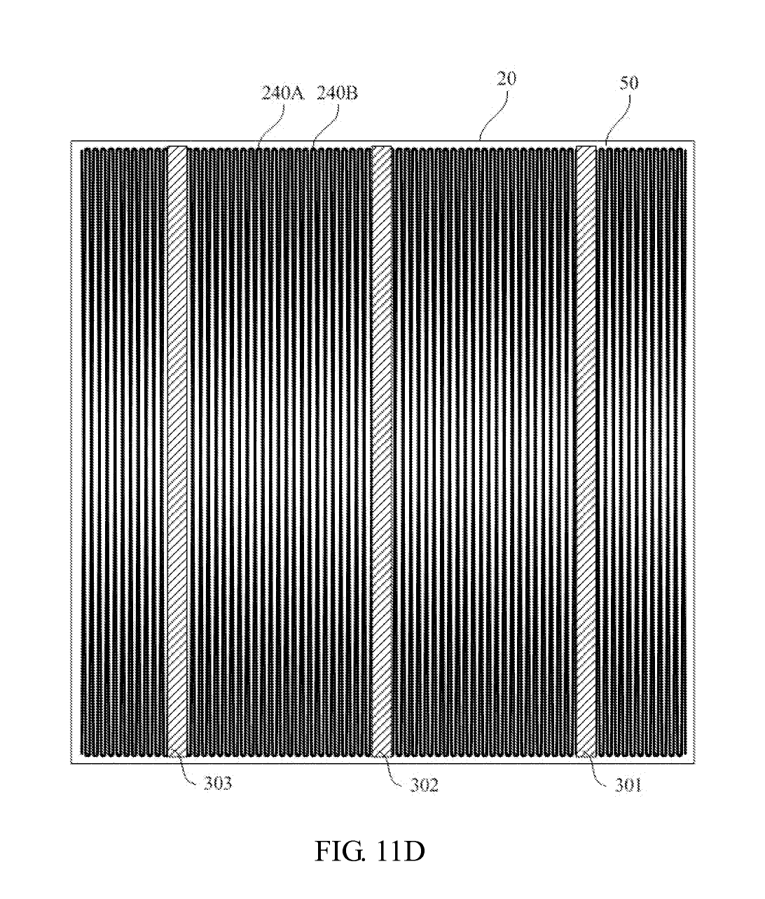

FIGS. 11A to 11D are bottom views of an ninth embodiment of a solar cell of the present invention, which shows a couple of continuous openings 230A, 230B, a couple of continuous electrodes 240A, 240B and a plurality of back bus bars 301, 302, 303.

In FIG. 11A, the two continuous openings 230A, 230B are formed in the passivation layer 50 of the second surface of the semiconductor substrate 20 (p-type or n-type); namely, the two continuous openings 230A, 230B are disposed at the back side of the semiconductor substrate 20. In this embodiment, the two continuous openings 230A, 230B are formed by respectively connecting a plurality of linear openings with each other, in which the linear openings are not orthogonal to the back bus bars 301, 302, 303 and the number of the linear openings is even, as shown in FIG. 11C. Moreover, the continuous opening 230A has two end points 239A, 239B disposed at one side of the semiconductor substrate 20; the continuous opening 230B has two end points 239C, 239D disposed at the other side of the semiconductor substrate 20. Further, the connecting portions 238A, 238B between the linear openings of the continuous openings 230A, 230B can be curve or sharp angle.

Please refer to FIGS. 11B and 11C, in which the two continuous electrodes 240A, 240B are connected with the aforementioned back bus bars 301, 302, 303. And, the continuous electrode 240A has two end points 249A, 249B disposed at a lateral side of the semiconductor substrate 20; the continuous electrode 240B has two end points 249C, 249D disposed at the other lateral side of the semiconductor substrate 20. Similarly, the connecting portions 248A, 248B between the linear electrodes of the continuous electrodes 240A, 240B are curve.

Please refer to FIG. 11D, showing one embodiment in which the back bus bars 301, 302, 303 of the FIG. 11C are aligned longitudinally rather than aligned transversely. This embodiment has the same advantages as mentioned above, so they are omitted.

In this embodiment, each continuous opening and electrode is formed by connecting two symmetrical linear structures, and the angle between each linear opening (electrode), and the back bus bars is 45 degrees. In some embodiments, the linear openings (electrodes) are asymmetrical with each other, and the angle between each linear opening (electrode) and the back bus bars is defined from 0 degree to 90 degrees.

In this embodiment, the end points are disposed at the same side of the semiconductor substrate, so that the continuous openings and the continuous electrodes are positioned easily during manufacturing so as to improve the preciseness and the yield rate.

In the embodiments mentioned above, the continuous opening and the continuous electrode are formed by connecting a plurality of straight lines with each other in which the straight lines are orthogonal to or not orthogonal to the back bus bars, or in which some of the straight lines are orthogonal to the back bus bars; that is to say, the angle between the straight lines and the back bus bars is defined from 0 degree to 90 degrees. Further, the continuous opening (electrode), has two end points disposed at the same side or at the two diagonal corners of the semiconductor substrate, and the connecting portions of the straight lines of the continuous opening (electrode) can be curve or shaped in a sharp angle.

In addition, the area the continuous electrode protruding from the surface of the passivation layer is at least larger than 5% of the area of the continuous opening. The continuous opening has the first width W1, which is defined from 10 micrometers to 300 micrometers; the portion of the continuous electrode which is protruding from the passivation layer 50 has the second width W2. The second width W2 is larger than the first width W1. The passivation layer 50 has the first depth H1 defined from 5 nanometers to 300 nanometers. The portion of the continuous electrode protruding from the passivation layer has the protruding depth defined from 5 micrometers to 40 micrometers. Additionally, the number of the straight lines of the continuous opening (electrode), is at a range between 2 to 300.

In addition, besides manufacturing the continuous openings and the continuous electrodes by laser cutting or etching methods, the continuous electrodes can be manufactured by firing as well.

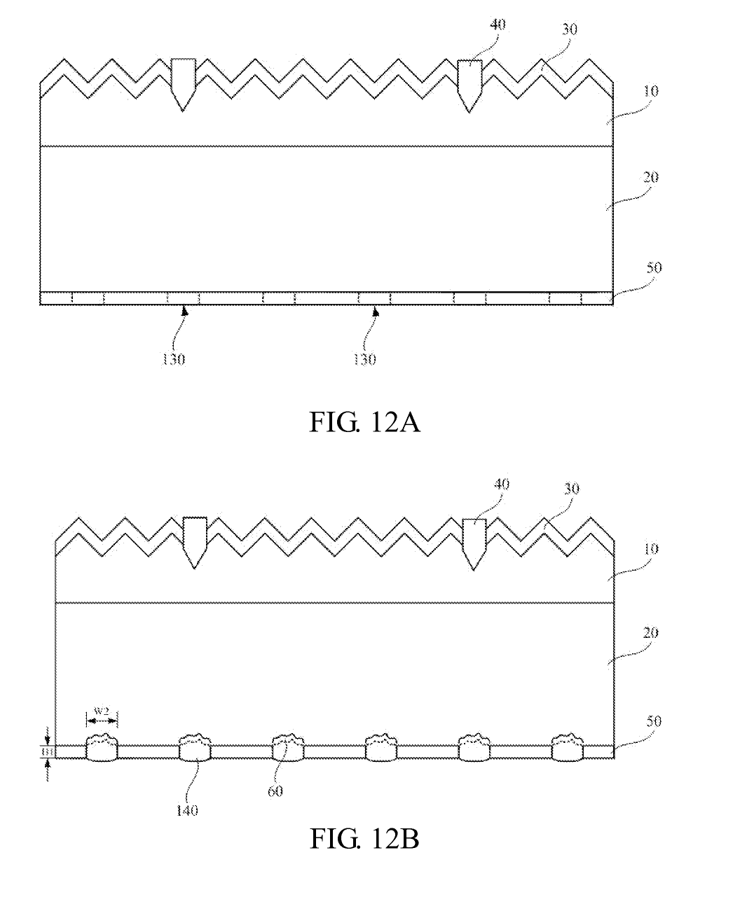

FIGS. 12A to 12B are cross-sectional views of the region 1 in FIG. and 1B along line A-A in which the continuous electrode is formed directly via co-firing method rather than forming the continuous opening in advance. In FIG. 12A, the continuous opening 130 is a virtual opening, and the position of the virtual opening is the position ready for manufacturing the continuous electrode 140. In FIG. 12B, conductive material is fired to the virtual opening by firing method so as to form the structure shown in FIG. 1B.

Via the firing method, the continuous electrode 140 is disposed at the passivation layer 50 and directly penetrate the passivation layer 50 so as the continuous electrode 140 is connecting to the second surface of the semiconductor substrate 20. The continuous electrode 140 has a width W2 defined from 10 micrometers to 300 micrometers. The passivation layer 50 has the first depth H1 defined from 5 nanometers to 300 nanometers. The depth the continuous electrode protruding from the passivation layer is defined from 5 micrometers to 40 micrometers. In this embodiment, the width W is 50 micrometers and the first depth H1 is 100 nanometers.

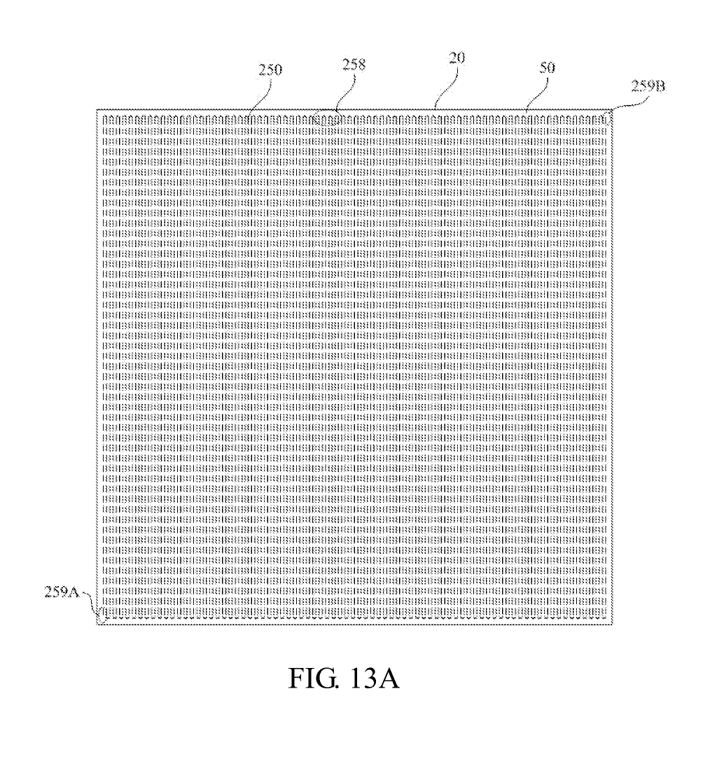

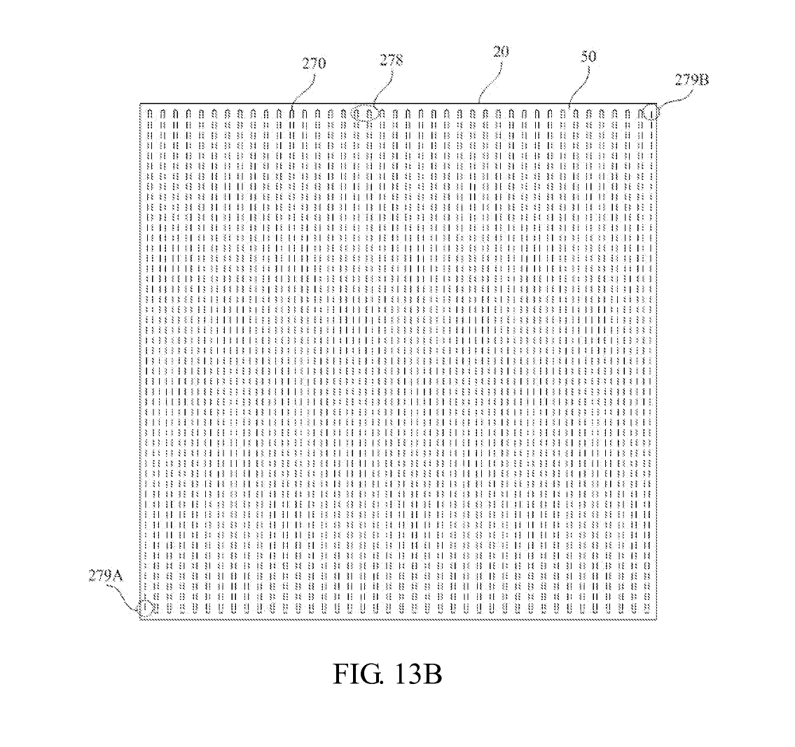

In the embodiments mentioned above, within the continuous opening (or the continuous electrode), the openings (or electrodes), are designed by concepts of continuous, bending and linearly connecting with each other. The linearity design concept can be embodied by solid lines, continuous dash lines or continuous dots, and in the embodiments mentioned above, solid lines are applied. FIG. 13A and FIG. 13B are schematic views for showing the linear openings (and the linear electrodes), in the continuous openings are embodied by dash lines which are respectively corresponding to the embodiments shown in FIG. 1A and FIG. 3A. In FIG. 13A, each parallel straight line of the continuous opening 250 is formed by dash lines and the continuous opening 250 also has two end points 259A, 259B and a plurality of connecting portions 258. In FIG. 13B, each straight line of the V-shaped continuous opening 270 is formed by dash lines and the continuous opening 270 also has two end points 279A, 279B and a plurality of connecting portions 278.

Consequently, the shape of the continuous opening and the continuous electrode in the disclosure is a continuous line, for instance, solid line and/or dash line. Further, in other embodiments, the continuous opening or the continuous electrode can be a non-linear line as curve line, wave line or jagged-like line. The detailed description about how to adapt the line shapes mentioned above into the continuous opening is known by those who are skilled in this art so as to be omitted.

In the embodiments mentioned above, when the continuous openings are applied by dash lines, the continuous electrode is preferred to be applied to cover the linear openings; or, a back electrode which is flat can also be applied to.

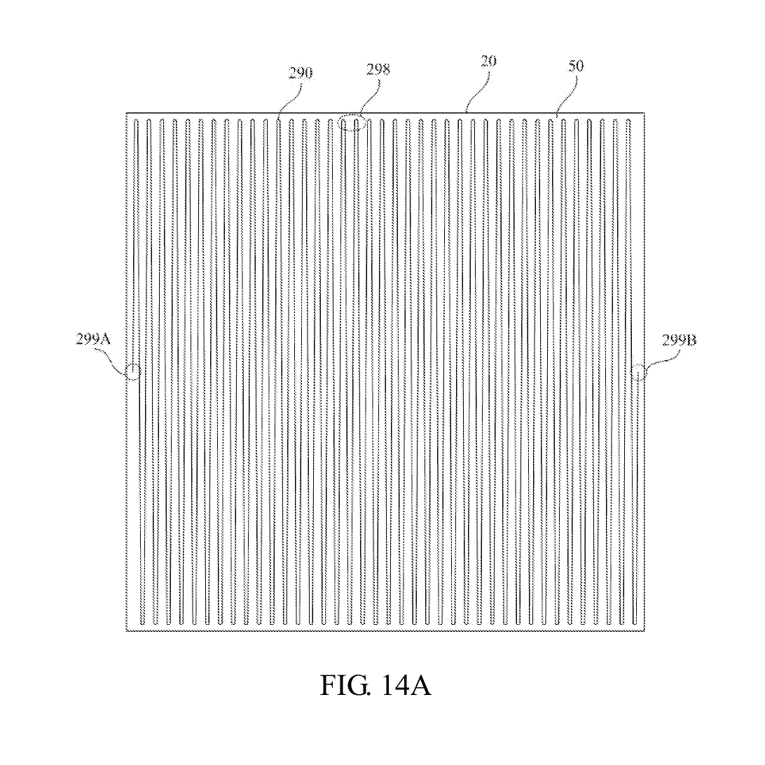

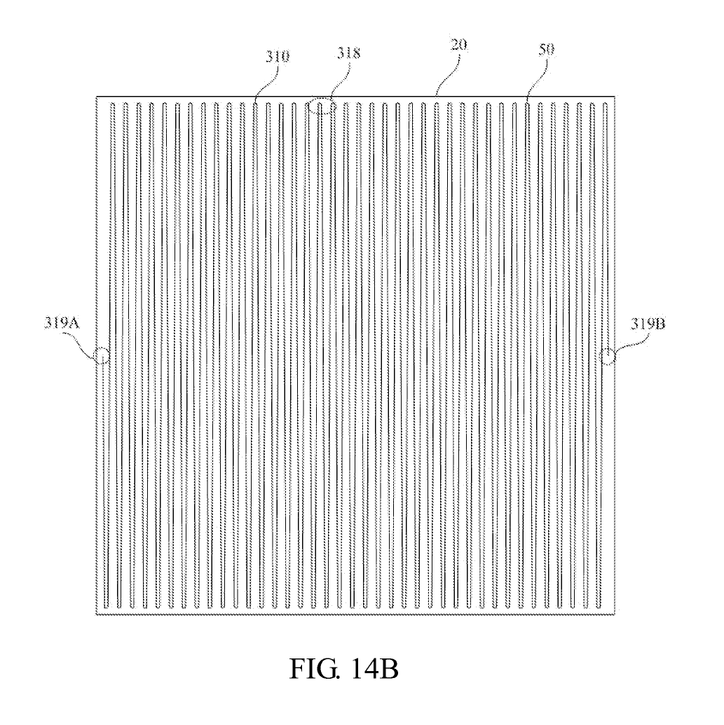

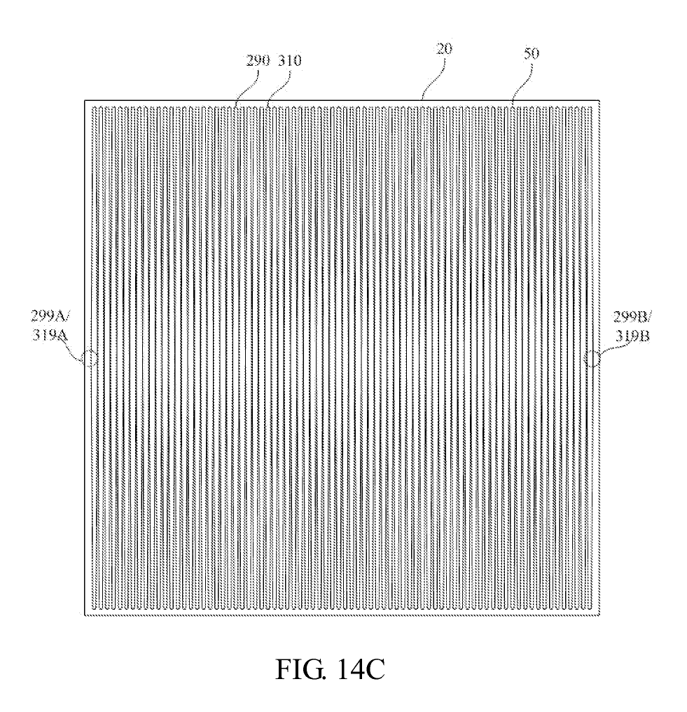

Furthermore, in the embodiments mentioned above, the two end points of each continuous opening (electrode), are disposed at the same side or at the two diagonal corners. In other embodiments, the two end points of each continuous opening (electrode), can also be respectively disposed at middle portions of two sides of the semiconductor substrate. FIGS. 14A to 14B are schematic views for showing the two end points of each continuous opening are disposed at the middle portions of the two opposite sides of the semiconductor substrate 20. In the embodiment shown in FIG. 14A, the two end points 299A, 299B of the continuous opening 290 are respectively disposed at the middle portions of the two opposite sides of the semiconductor substrate 20, and the continuous opening 290 has a plurality of connecting portions 298. In the embodiment shown in FIG. 14B, the two end points 319A, 319B of the continuous opening 310 are respectively disposed at the middle portions of the two opposite sides of the semiconductor substrate 20, and the continuous opening 310 has a plurality of connecting portions 318.

As shown in FIG. 14A and FIG. 14B, the continuous opening 290 and the continuous opening 310 are substantially symmetrical. Once the two continuous openings 290, 310 are formed at a same semiconductor substrate 20, the two end points 299A, 299B of the continuous openings 290 will connected with the two end points 319A, 319B of the continuous openings 310, as shown in FIG. 14C, the end point 299A is connected with the end point 319A, and the end point 299B is connected with the end point 319B. For the embodiments with the end points being connected with each other, there seems to be substantially no end points in the embodiments.

Consequently, each continuous opening or each continuous electrode includes two end points disposed at the same side, the two diagonal corners, or the middle portions of the two opposite sides of the second surface of the semiconductor substrate; the two end points may also be connected with other. In other embodiments, the two end points can be disposed at an arbitrary position of the second surface of the semiconductor substrate, such as at the one-third, one-fourth, one-fifth of the two opposite sides or so forth.

Similarly, the electrode for covering the continuous opening can be applied by the continuous electrode or the back electrode which is flat.

In the embodiments mentioned above, the back electrode is disposed between the passivation layer and the back bus bars; in other embodiments, the back bus bars can also be disposed between the passivation layer and the back electrode, and the design concepts shown in FIG. 1A to FIG. 14C. The details of how these embodiments works with the design concepts are known by skilled in this art so as to be omitted.

While the present invention has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A solar cell, comprising:
a semiconductor substrate, having a first surface and a second surface;
a passivation layer, disposed on the second surface, having at least one continuous opening;
at least one back electrode, connecting to the semiconductor substrate through the continuous opening; and
at least one back bus bar, electrically connected to the back electrode;
wherein the back electrode is disposed between the passivation layer and the back bus bar or the back bus bar is disposed between the passivation layer and the back electrode.

2. The solar cell according to claim 1, wherein the continuous opening comprises two end points, the two end points are disposed at the same side, at the two diagonal corners or at the middle portions of the two opposite sides of the second surface of the semiconductor substrate, or the end points of the continuous opening are connected with each other.

3. The solar cell according to claim 1, wherein the solar cell comprises at least two continuous openings, and the end points of the two continuous openings are disposed at the same side or at the two diagonal corners of the second surface of the semiconductor substrate, or the end points of the two continuous openings are connected with each other.

4. The solar cell according to claim 3, wherein the continuous openings are interlaced arrangement or parallel arrangement by a predetermined interval.

5. The solar cell according to claim 1, wherein the continuous opening is formed by connecting a plurality of linear openings with each other, and an angle between the linear openings and the back bus bar is defined from 0 degree to 90 degrees.

6. The solar cell according to claim 5, wherein the connecting portion between the adjacent linear openings of the continuous opening is capable of being curve or sharp angle.

7. The solar cell according to claim 5, wherein the number of the linear openings of each continuous opening is at a range between 2 to 300.

8. The solar cell according to claim 1, wherein the continuous opening corresponds to at least one back bus bar.

9. The solar cell according to claim 1, wherein the back electrode is at least one continuous electrode, the continuous electrode is disposed on the corresponding continuous opening.

10. The solar cell according to claim 1, wherein the back electrode is a flat electrode overlapping a whole back side of the solar cell and disposing on the passivation layer.

11. The solar cell according to claim 3, wherein the back electrode further comprises at least two continuous electrodes, each continuous electrode is disposed on each corresponding continuous opening.

12. The solar cell according to claim 9, wherein a first area of the continuous electrode protruding from the passivation layer is at least larger than 5% of a second area of the continuous opening.

13. The solar cell according to claim 11, wherein a first area the continuous electrode protruding from the passivation layer is at least larger than 5% of a second area of the continuous opening.

14. The solar cell according to claim 1, wherein the continuous opening has a first width defined from 10 micrometers to 300 micrometers.

15. The solar cell according to claim 12, the continuous opening has a first width defined from 10 micrometers to 300 micrometers, the portion of the continuous electrode which is protruding from the passivation layer has a second width, the second width is larger than the first width.

16. The solar cell according to claim 13, the continuous opening has a first width defined from 10 micrometers to 300 micrometers, the portion of the continuous electrode which is protruding from the passivation layer has a second width, the second width is larger than the first width.

17. The solar cell according to claim 1, wherein the passivation layer has a first depth defined from 5 nanometers to 300 nanometers.

18. The solar cell according to claim 9, wherein a depth of the portion of the continuous electrode which is protruding from the passivation layer is defined from 5 micrometers to 40 micrometers.

19. A solar cell, comprising:
a semiconductor substrate, having a first surface and a second surface;
a passivation layer, disposed on the second surface;
at least one continuous electrode, disposed on the passivation layer and penetrating the passivation layer so as to connect to the second surface of the semiconductor substrate; and
at least one back bus bar, connected to the continuous electrode.

20. The solar cell according to claim 19, wherein the continuous opening comprises two end points, the two end points are disposed at the same side, at the two diagonal corners or at the middle portions of the two opposite sides of the second surface of the semiconductor substrate.

21. The solar cell according to claim 19, wherein the at least one continuous opening comprises at least two continuous openings, and the end points of the two continuous openings are disposed at the same side or at the two diagonal corners of the second surface of the semiconductor substrate, or the end points of the two continuous linear openings are connected with each other.

22. The solar cell according to claim 21, wherein the continuous openings are interlaced arrangement or parallel arrangement by a predetermined interval.

23. The solar cell according to claim 19, wherein the continuous opening is formed by connecting a plurality of linear openings with each other, and an angle between the linear openings and the back bus bar is defined from 0 degree to 90 degrees.

24. The solar cell according to claim 23, wherein the connecting portion between the adjacent linear openings of the continuous opening is capable of being curve or sharp angle.

25. The solar cell according to claim 23, wherein the number of the linear openings of each continuous opening is at a range between 2 to 300.

26. The solar cell according to claim 19, wherein each continuous electrode corresponds to at least one back bus bar.

27. The solar cell according to claim 19, wherein the portion of the continuous electrode which is protruding from the passivation layer has a width defined from 10 micrometers to 300 micrometers.

28. The solar cell according to claim 19, wherein the passivation layer has a first depth defined from 5 nanometers to 300 nanometers.

29. The solar cell according to claim 19, wherein a depth of the portion of the continuous electrode which is protruding from the passivation layer is defined from 5 micrometers to 40 micrometers.
